(19) United States
(12) Patent Application Publication
(10) Pub. No.: US 2026/0126772 A1
(43) Pub. Date: May 7, 2026

(54) SYSTEM, DEVICE, AND METHOD FOR A MANUFACTURING PROCESS

(71) Applicant: Samsung Electronics Co., Ltd., Suwon-si (KR)

(72) Inventors: Jaewon LEE, Suwon-si (KR); Namyeong KWON, Suwon-si (KR)

(73) Assignee: Samsung Electronics Co., Ltd., Suwon-si (KR)

(21) Appl. No.: 19/203,731

(22) Filed: May 9, 2025

(30) Foreign Application Priority Data
Nov. 4, 2024 (KR) 10-2024-0154167

(51) Int. Cl. G05B 19/18

(52) U.S. Cl. CPC G05B 19/188; G05B 2219/45031

(57) ABSTRACT

Provided is a system, device, and method. The method includes estimating, using a first model, respective first yields of first wafers based on first data on a plurality of factors about a semiconductor manufacturing process regarding the plurality of first wafers, the first data obtained before the semiconductor manufacturing process of the plurality of first wafers has been completed, generating, using a second model generated based on the first model, respective yield contribution values of the plurality of factors based on the first data, data on the estimated respective first yields of the plurality of first wafers, second data on the plurality of factors regarding a plurality of second wafers of which the semiconductor manufacturing process has completed, and determining one or more factors, among the plurality of factors, that contribute to a yield reduction based on the generated respective yield contribution values of the plurality of factors.

### CROSS-REFERENCE TO RELATED APPLICATIONS

This application claims the benefit under 35 USC § 119(a) of Korean Patent Application No. 10-2024-0154167, filed on Nov. 4, 2024, in the Korean Intellectual Property Office, the disclosure of which is incorporated herein by reference in its entirety.

### BACKGROUND

### 1. Field

One or more embodiments relate to a system, device, and method for a manufacturing process.

### 2. Description of Related Art

The semiconductor industry has diversified and become more sophisticated in demand, from personal computers in the past to mobile devices, home appliances, and automobiles, along with the development of the industry. Further, there is a higher integration of semiconductor devices in such devices. Semiconductor circuitries are being formed with ultra-fine line widths.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method with respect to a semiconductor manufacturing process includes estimating, using a first model, respective first yields of a plurality of first wafers based on first data on a plurality of factors about a semiconductor manufacturing process regarding the plurality of first wafers obtained before the semiconductor manufacturing process of the plurality of first wafers has been completed, generating, using a second model generated based on the first model, respective yield contribution values of the plurality of factors based on the first data, data on the estimated respective first yields of the plurality of first wafers, second data on the plurality of factors regarding a plurality of second wafers of which the semiconductor manufacturing process has completed, and data on respective second yields of the plurality of second wafers, determining one or more factors, among the plurality of factors, that contribute to a yield reduction based on the generated respective yield contribution values of the plurality of factors.

The plurality of factors may include factors regarding a plurality of equipment pieces used in the semiconductor manufacturing process and factors regarding a plurality of measurement items that may be measured in the semiconductor manufacturing process, where data, among the first data, regarding one wafer of the plurality of first wafers may include category data on one or more pieces of first equipment used among the plurality of equipment pieces in a first process of the semiconductor manufacturing process performed with respect to the one wafer, category data on one or more pieces of second equipment predetermined among the plurality of equipment pieces to be used in a second process of the semiconductor manufacturing process with respect to the one wafer, measurement data on one or more first measurement items, among the plurality of measurement items, that have been measured with respect to the one wafer in the semiconductor manufacturing process, and measurement data on one or more second measurement items, among the plurality of measurement items, predetermined to be measured with respect to the first wafer in the semiconductor manufacturing process, and where another data, among the second data, regarding another one wafer of the plurality of second wafers may include category data on the plurality of equipment pieces with respect to the other one wafer and measurement data on the plurality of measurement items with respect to the other one wafer.

The category data on the one or more pieces of second equipment may include corresponding data obtained based on process history of the one or more pieces of second equipment, and the measurement data on the one or more second measurement items may include other corresponding data obtained based on process history of the one or more second measurement items.

The method may further include training the first model based on the second data and the data on the respective second yields of the plurality of second wafers.

The first model may include a neural network including at least a plurality of layers, and the method further include generating the second model based on weights of the plurality of layers, where the second model may include an explainable artificial intelligence (XAI) model.

The determining of the one or more factors that contribute to the yield reduction may include identifying date-dependent changes in respective yield reduction contribution rankings of the plurality of factors, based on the generated respective yield contribution values of the plurality of factors, identifying, as the determined one or more factors that contribute to the yield reduction, corresponding one or more factors, among the plurality of factors, of which the respective yield reduction contribution rankings rise based on the date-dependent changes in the respective yield reduction contribution rankings of the plurality of factors.

The identifying of the date-dependent changes in the may include generating a plurality of wafer sets by grouping wafers for which an identical process in the semiconductor manufacturing process was performed on an identical date among the plurality of first wafers and the plurality of second wafers, identifying the generated respective yield contribution values of the plurality of factors for each of the plurality of wafer sets, determining the respective yield reduction contribution rankings of the plurality of factors for each of the plurality of wafer sets based on the identified generated respective yield contribution values.

A yield reduction contribution ranking of a first factor for a first wafer set among the respective yield reduction contribution rankings of the plurality of factors for each of the plurality of wafer sets may include one of a yield reduction contribution ranking corresponding to a date on which a first process of the semiconductor manufacturing process corresponding to the first factor is executed for the first wafer set, a yield reduction contribution ranking corresponding to a date on which a second process of the semiconductor manufacturing process corresponding to the first factor is predetermined to be executed for the first wafer set, a yield reduction contribution ranking corresponding to a completion date of the first wafer set with respect to the semiconductor manufacturing process, a yield reduction contribution ranking corresponding to an expected completion date of the first wafer set with respect to the semiconductor manufacturing process.

The determined respective yield reduction contribution rankings of the plurality of factors for a first wafer set, among the determined respective yield reduction contribution rankings of the plurality of factors for each of the plurality of wafer sets, may be determined to be higher as the identified respective yield contribution values of the plurality of factors for the first wafer set are lower.

The identified generated respective yield contribution value of a first factor for a first wafer set, among the identified generated respective yield contribution values of the plurality of factors for each of the plurality of wafer sets, may be determined as an average value of the generated respective yield contribution values of the first factor corresponding to wafers included in the first wafer set.

The plurality of first wafers may include one wafer for which the semiconductor manufacturing process may be set to be completed within a first period of time with reference to a set date, and the plurality of second wafers may include another one wafer for which the semiconductor manufacturing process was completed within a second period of time with reference to the set date.

The method may further include providing a user terminal with information on the one or more factors, where the information on the one or more factors may include at least one of information indicating date-dependent change in yield reduction contribution rankings of the one or more factors, information on equipment corresponding to the one or more factors, and information corresponding to a measurement item corresponding to the one or more factors.

In one general aspect, one or more embodiments include a non-transitory computer-readable recording medium storing code, which when executed by one or more processors, configures the one or more processors to execute one or more or all operations described herein.

In one general aspect, an electronic device includes a memory storing code, and one or more processors configured to execute the code, wherein, execution of the code by the processor, configures the one or more processors to estimate, using a first model, respective first yields of a plurality of first wafers based on first data on a plurality of factors about the semiconductor manufacturing process regarding the plurality of first wafers, the first data obtained before the semiconductor manufacturing process of the plurality of first wafers has been completed, generate, using a second model generated based on the first model, respective yield contribution values of the plurality of factors based on the first data, data on the estimated respective first yields of the plurality of first wafers, second data on the plurality of factors regarding a plurality of second wafers of which the semiconductor manufacturing process has completed, and data on respective second yields of the plurality of second wafers, determine one or more factors, among the plurality of factors, that contribute to a yield reduction based on the generated respective yield contribution values of the plurality of factors.

The plurality of factors may include factors regarding a plurality of equipment pieces used in the semiconductor manufacturing process and factors regarding a plurality of measurement items that may be measured in the semiconductor manufacturing process, where data, among the first data, regarding one wafer of the plurality of first wafers may include category data on one or more pieces of first equipment used among the plurality of equipment pieces in a first process of the semiconductor manufacturing process performed with respect to the one wafer, category data on one or more pieces of second equipment predetermined among the plurality of equipment pieces to be used in a second process of the semiconductor manufacturing process with respect to the one wafer, measurement data on one or more first measurement items, among the plurality of measurement items, that have been measured with respect to the one wafer in the semiconductor manufacturing process, and measurement data on one or more second measurement items, among the plurality of measurement items, predetermined to be measured with respect to the first wafer in the semiconductor manufacturing process, and where another data, among the second data, regarding another one wafer of the plurality of second wafers may include category data on the plurality of equipment pieces with respect to the other one wafer and measurement data on the plurality of measurement items with respect to the other one wafer.

The category data on the one or more pieces of second equipment may include corresponding data obtained based on process history of the one or more pieces of second equipment, and the measurement data on the one or more second measurement items may include other corresponding data obtained based on process history of the one or more second measurement items.

The execution of the code further may configure the one or more processors to train the first model based on the second data and the data on the respective second yields of the plurality of second wafers.

The first model may include a neural network including at least a plurality of layers, and the execution of the code may further configure the one or more processors to generate the second model based on weights of the plurality of layers, where the second model may include an explainable artificial intelligence (XAI) model.

For the determining of the one or more factors that contribute to the yield reduction, the execution of the code may configure the one or more processors to identify date-dependent changes in respective yield reduction contribution rankings of the plurality of factors, based on the generated respective yield contribution values of the plurality of factors, and identify, as the determined one or more factors that contribute to the yield reduction, corresponding one or more factors, among the plurality of factors, of which the respective yield reduction contribution rankings rise based on the date-dependent changes in the respective yield reduction contribution rankings of the plurality of factors.

For the identifying of the date-dependent changes in the respective yield reduction contribution rankings of the plurality of factors, the execution of the code may configure the one or more processors to generate a plurality of wafer sets by grouping wafers for which an identical process in the semiconductor manufacturing process was performed on an identical date among the plurality of first wafers and the plurality of second wafers, identify the generated respective yield contribution values of the plurality of factors for each of the plurality of wafer sets, and determine the respective yield reduction contribution rankings of the plurality of factors for each of the plurality of wafer sets based on the identified generated respective yield contribution values.

Other features and aspects will be apparent from the following detailed description, the drawings, and the claims.

### BRIEF DESCRIPTION OF THE DRAWINGS

FIG. 1 illustrates a system with an electronic device that identifies factors contributing to yield reduction according to one or more embodiments;

FIG. 2 illustrates a system with an electronic device that identifies factors contributing to yield reduction according to one or more embodiments;

FIG. 3 is a flowchart of a method of an electronic device for providing information on factors contributing to yield reduction according to one or more embodiments;

FIG. 4 is a flowchart of a method of an electronic device for providing information on factors contributing to yield reduction according to one or more embodiments;

FIG. 5 illustrates an example of data for a plurality of factors related to a semiconductor manufacturing process according to one or more embodiments;

FIG. 6 illustrates a method of an electronic device for determining yield reduction contribution rankings of a plurality of factors for each of a plurality of wafer sets according to one or more embodiments;

FIG. 7 illustrates a method of an electronic device for determining factors contributing to yield reduction according to one or more embodiments;

FIG. 8 illustrates a method of an electronic device for determining factors contributing to yield reduction according to one or more embodiments;

FIG. 9 is a flowchart of a method of an electronic device for providing information on factors contributing to yield reduction according to one or more embodiments;

FIG. 10 illustrates a method according to one or more embodiments; and

FIG. 11 illustrates a semiconductor system with an electronic device according to one or more embodiments.

FIG. 12 illustrates a block diagram of the electronic device 100 according to an example embodiment.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order (e.g., a certain order). Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example”, “embodiment”, and “example embodiment” herein have a same meaning (e.g., the phrasing ‘in an or one example’ has a same meaning as ‘in an or one embodiment’ and ‘in an or one example embodiment’), and “one or more examples” has a same meaning as “one or more embodiments” and “one or more example embodiments”. Still further, each of multiple or all separately described an/one “example”, “embodiment”, or “example embodiment” herein may be included, in combination, in a same embodiment in any combination.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof.

Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C” (e.g., each phrase may include any one of the respective items alone, all of the items listed together, and all possible combinations thereof), and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

As noted above, semiconductor circuities are being generated with more fine line widths, which is found to have an increased impact on yield. It is found that yield improvement may be an important factor in the semiconductor process. Yield can be generally defined as output relative to input, and, generally in the semiconductor industry, yield can be defined as a total number of chips (e.g., repeated separate circuitries) that can be produced per wafer.

Example monitoring systems may be used to manage complex processes, control processes, and generate data in a semiconductor manufacturing system. As yield management is very complex and intertwined with numerous operations (e.g., numbering between 200 and 300 individual processes), with multiple equipment and operating conditions in each process, and since it may take a long time to complete a semiconductor manufacturing process for one wafer, it is found that there may be a need for an improved semiconductor manufacturing process (e.g., for such yield improvements), compared to processes that may only include statistical or engineer-empirical analyses.

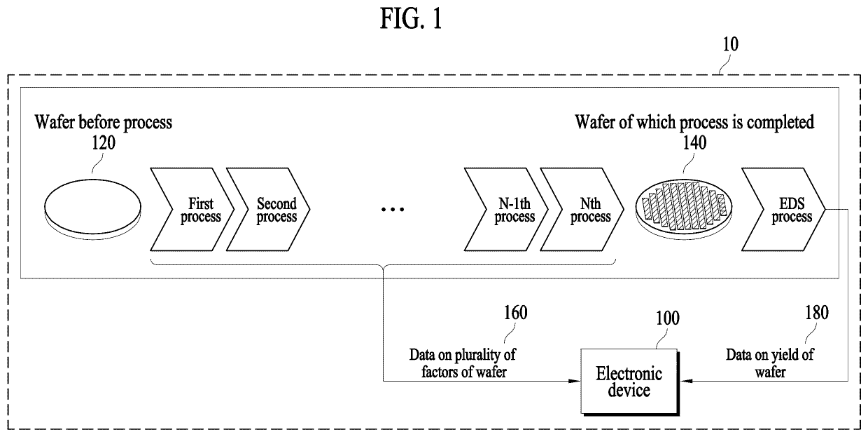

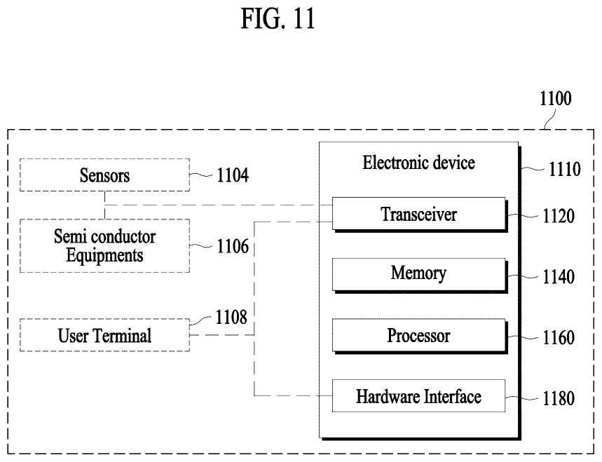

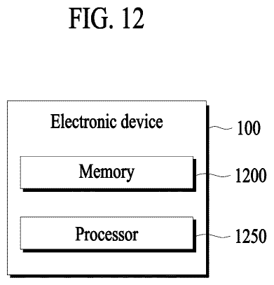

FIG. 1 illustrates a system with an electronic device that identifies factors contributing to yield reduction according to one or more embodiments. Electronic devices referred to herein include one or more processors, i.e., as processor circuitry, that are configured to perform the described respective operations thereof, through the one or more processors alone or as combination of the one or more processors and code executed by the one or more processors to configure the one or more processors to perform the described respective operations of the corresponding electronic device. For example, the electronic devices may include one or more memories that store such code. As further non-limiting examples, such electronic devices described herein may correspond to the electronic devices 1110 or 100 or FIGS. 11 and 12, and while an electronic device is described such descriptions also refer to separate corresponding electronic devices that are respectively configured to perform one or more operations of various combinations described herein with respect to the electronic device. The illustrated processes in FIG. 1 may be performed by a plurality of equipment pieces that may also be included in the illustrated semiconductor system 10 of FIG. 1. As a non-limiting example, the semiconductor system 10 of FIG. 1 may correspond to the semiconductor system 1100 of FIG. 11.

Referring to FIG. 1, an electronic device 100 may identify data on a plurality of factors related to a semiconductor manufacturing process of a semiconductor manufacturing process-finished wafer. For example, the electronic device 100 may obtain category data for a plurality of equipment pieces used in a semiconductor manufacturing process of a semiconductor manufacturing process-finished wafer and measurement data for a plurality of measurement items that are measured in the semiconductor manufacturing process of the semiconductor manufacturing process-finished wafer.

As illustrated in FIG. 1, a semiconductor manufacturing process-finished wafer 140 may be generated as the result of various processes, such as oxidation process, photo process, etching process, deposition process, ion implantation process, metalization process and measurement process, as non-limiting examples, being performed n times on a wafer 120 according to a set order and combination, before completing the generation of the semiconductor manufacturing process-finished wafer 140. Such various processes may be performed in any combination by the plurality of equipment pieces. The electronic device 100 may obtain data 160 about a plurality of factors of a semiconductor manufacturing process of a wafer, which is data (e.g., sequential data) that includes category data on the equipment used in the semiconductor manufacturing process of the semiconductor manufacturing process-finished wafer 140 and measurement data that is measured on the semiconductor manufacturing process-finished wafer 140. As a non-limiting example, each equipment (or pieces of equipment) used in the respective processes may provide their respective category data to the electronic device 100 and respective sensors (e.g., co-positioned near, such as immediately before, at/in, and/or after each of multiples of such equipment and/or between each of multiples of such equipment) in the semiconductor system 10 may provide their generated/captured measurement data to the electronic device 100. As a non-limiting examples, such sensors may correspond to the sensors 1104 of FIG. 11.

Herin, a plurality of factors regarding the semiconductor manufacturing process may include respective factors regarding the plurality of equipment pieces (e.g., respective category data) used in the semiconductor manufacturing process and respective factors related to the plurality of measurement items (e.g., respective measurement data) that are measured in the semiconductor manufacturing process. The factors regarding the plurality of equipment pieces used in the semiconductor manufacturing process may include equipment identification information (EQP_ID), equipment model information (EQP_MODEL), identification information of a chamber within the equipment (EQP_CHAMBER_ID), process program identification (PPID) information (EQP_PPID), and/or reticle information (EQP_RETICLE). However, the factors regarding the plurality of equipment pieces are not limited thereto. Further, the factors relating to the plurality of measurement items that are measured in the semiconductor manufacturing process may include temperature, pressure, gas flow rate, humidity, thickness, flatness, line width, and/or reflectivity of the sample wafer. However, the factors relating to the plurality of measurement items are not limited thereto.

According to an example embodiment, the electronic device 100 may identify data on the yield of a semiconductor manufacturing process-finished wafer. For example, referring to FIG. 1, based on the results of an electrical die sorting (EDS) process for the semiconductor manufacturing process-finished wafer 140, the electronic device 100 may obtain data 180 on the yield of a wafer, which represents the percentage value of the number of determined prime good chips produced for the wafer compared to a maximum number of chips designed on one sheet for the wafer.

According to an example embodiment, based on data on the plurality of factors related to the semiconductor manufacturing process of process-finished wafers and data on the yield of process-finished wafers, the electronic device 100 may determine which factor(s) are contributing to a yield reduction of a wafer among the plurality of factors. For example, with an input of the data 160 on the plurality of factors of the wafer and the data 180 on the yield of the wafer into a model (e.g., a machine-learning related model) configured to yield contribution values of the plurality of factors, the electronic device 100 may identify the yield contribution values of the plurality of factors. Subsequently, the electronic device 100 may identify the yield reduction contribution rankings of the plurality of factors based on the yield contribution values of the plurality of factors, and determine a factor with a rising yield reduction contribution ranking among the plurality of factors as a final factor contributing to yield reduction.

When the electronic device 100 determines the factors contributing to yield reduction based solely on data from process-finished wafers or FAB-OUT wafers, the impact of already improved and/or changed process(s) may not be considered, and thus, there is a risk that factors that may have already improved are determined as factors contributing to the yield reduction, and no new yield reduction contributing factors that arise in the ongoing process may be discovered. Further, since it may take multiple months to complete the semiconductor manufacturing process for one wafer, it may also take multiple months to determine which factors are contributing to yield reduction.

Therefore, in order to further discover factors that contribute to yield reduction in the semiconductor manufacturing process, along with factors that contributed to the yield reduction in the past, in addition to analyzing already process-finished wafers, it may be beneficial to additionally analyze wafers that are within the semiconductor manufacturing process (i.e., IN-fabrication (FAB) wafers) for which real-time data may be obtained or available, but by itself may not be sufficient for more accurate yield reduction determinations because the corresponding semiconductor manufacturing process has not yet been completed.

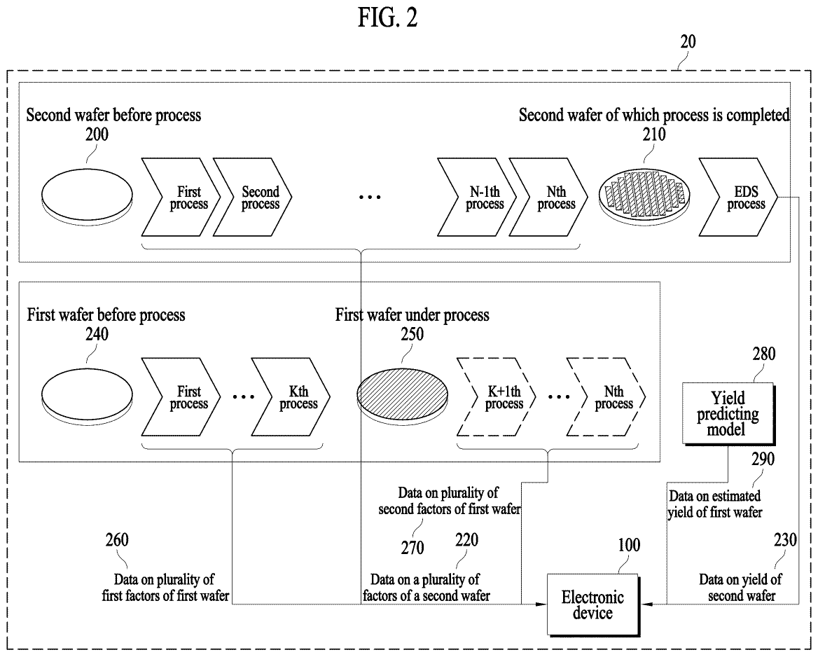

FIG. 2 illustrates a method of an electronic device that identifies factors contributing to yield reduction according to one or more embodiments. Example content that overlaps with the above-described content in relation to FIG. 1 will be briefly explained or omitted. The illustrated processes in FIG. 2 may be respectively performed by a plurality of equipment pieces that may also be included in the illustrated semiconductor system 20 of FIG. 2. As a non-limiting example, the semiconductor system 20 of FIG. 1 may correspond to the semiconductor system 1100 of FIG. 11. The semiconductor system 20 of FIG. 2 may also correspond to the semiconductor system 10 of FIG. 1.

According to an example embodiment, an electronic device 100 (e.g., the electronic device 100 of FIG. 1 and/or the electronic devices of FIG. 11 or 12, as non-limiting examples) may identify data on a plurality of factors related to the semiconductor manufacturing process of a semiconductor manufacturing process-finished wafer. More specifically, the electronic device 100 may obtain category data for a plurality of equipment pieces used in the semiconductor manufacturing process of semiconductor manufacturing process-finished wafer(s), and measurement data for a plurality of measurement items that are measured in the semiconductor manufacturing process of such process-finished wafer(s). As a non-limiting example, each equipment (or pieces of equipment) used in the respective processes may provide their respective category data to the electronic device 100 and respective sensors (e.g., co-positioned near, such as immediately before, at/in, and/or after each of multiples of such equipment and/or between each of multiples of such equipment) in the semiconductor system 20 may provide their generated/captured measurement data to the electronic device 100. As a non-limiting examples, such sensors may correspond to the sensors 1104 of FIG. 11.

For example, referring to FIG. 2, a second wafer 210 for which process is complete may be generated as a result of various processes, such as oxidation process, photo process, etching process, deposition process, ion implantation process, metallization process and measurement process, being performed n times on a second wafer 200 according to a set order and combination before processing. Such various processes may be performed in any combination by the plurality of equipment pieces. The electronic device 100 may obtain data 220 for a plurality of factors of a second wafer, which may be sequential data and may include category data on equipment used in the semiconductor manufacturing process of the second wafer 210 for which the semiconductor manufacturing is completed and the measurement data that is measured for the second wafer 210 for which the semiconductor manufacturing process is completed.

According to an example embodiment, the electronic device 100 may identify data on the yield of a semiconductor manufacturing-finished wafer. For example, referring to FIG. 2, based on the EDS process results for the second wafer 210 for which the semiconductor manufacturing process is completed, the electronic device 100 may obtain data 230 on the yield of the second wafer, and the data 230 represents the percentage value of the number of prime good chips produced compared to the maximum number of chips designed for one second wafer.

According to an example embodiment, the electronic device 100 may identify data on factors corresponding to the semiconductor manufacturing process performed on the wafer while the semiconductor manufacturing process is in progress. More specifically, the electronic device 100 may obtain category data for one or more pieces of first equipment used in processing a wafer within (i.e., an IN-FAB wafer) the semiconductor manufacturing process, and measurement data for one or more first measurement items that are measured on the or another wafer within (i.e., the or another IN-FAB wafer) the semiconductor manufacturing process.

For example, referring to FIG. 2, as a result of k number of processes being performed on a first wafer 240, before all processes are performed among n number of processes that make up the semiconductor manufacturing process, a first wafer 250 within the semiconductor manufacturing process may be manufactured. The electronic device 100 may obtain data 260 for one or more first factors of the first wafer, which may be sequential data and may include category data on equipment used in the semiconductor manufacturing process of the first wafers 250 within the semiconductor manufacturing process and measurement data of the first wafers 250 within the semiconductor manufacturing process.

According to an example embodiment, the electronic device 100 may identify data on factors corresponding to a semiconductor manufacturing process to be performed on a wafer that is within the semiconductor manufacturing process. More specifically, based on the semiconductor manufacturing process history of the equipment to be used in the semiconductor manufacturing process of the wafer within the semiconductor manufacturing process and the semiconductor manufacturing process history of the measurement items to be measured for the wafer within the semiconductor manufacturing process, the electronic device 100 may obtain category data for one or more pieces of second equipment to be used in processing a wafer that is within the semiconductor manufacturing process, and measurement data for one or more second measurement items to be measured for the wafer that is within the semiconductor manufacturing process.

For example, the electronic device 100 may identify k+1th process to nth process that are not yet performed on the first wafer 250 within the semiconductor manufacturing process, and identify one or more second factors corresponding to the k+1th process to the nth process. Subsequently, based on the semiconductor manufacturing process history of one or more second factors, the electronic device 100 may identify the most recently obtained data for one or more second factors. The electronic device 100 may replace data 270 for one or more second factors of the first wafer with the most recently obtained data for one or more second factors (imputation).

However, the method by which the electronic device 100 replaces data for factors corresponding to processes of the semiconductor manufacturing process not performed on the first wafer is not limited to what is described above. The electronic device 100 may replace such data that has not been obtained through various methods.

According to an example embodiment, the electronic device 100 may identify data on the estimated yield of a wafer within the semiconductor manufacturing process. For example, referring to FIG. 2, the electronic device 100 may identify data 290 for the estimated yield of the first wafer by inputting the data 260 for one or more first factors of the first wafer and the data 270 for one or more second factors of the first wafer into a yield predicting model 280.

Here, as an artificial intelligence (AI) model for predicting yield based on data on a plurality of factors of a wafer, the yield predicting model 280 may be trained based on the data 220 on a plurality of factors of the second wafer and the data 230 on yield of the second wafer.

According to an example embodiment, the electronic device 100 may determine a factor contributing to yield reduction of a wafer among a plurality of factors based on data on a plurality of factors related to the semiconductor manufacturing process of a wafer that is within (i.e., a wafer ‘being processed within’ or a wafer ‘under’) the semiconductor manufacturing process, data on estimated yield of the wafer that is within the semiconductor manufacturing process, data on a plurality of factors in process-finished wafers and data on the yield of the semiconductor manufacturing process-finished wafer.

For example, the electronic device 100 may identify the yield contribution values of a plurality of factors by inputting the data 220 on the plurality of factors of the second wafer, the data 230 on the yield of the second wafer, the data 260 on one or more first factors of the first wafer, the data 270 on one or more second factors of the first wafer and the data 290 on the estimated yield of the first wafer into the model to determine the yield contribution values of the plurality of factors. Subsequently, the electronic device 100 may identify the yield reduction contribution ranking of a plurality of factors based on the yield contribution values of the plurality of factors, and determine a factor with a rising yield reduction contribution ranking among a plurality of factors as a factor contributing to yield reduction or a factor (e.g., for a corresponding process) that needs to be improved.

As such, the electronic device 100 may additionally take account of data from IN-FAB wafers to determine yield reduction contribution factors to discover new factors that may arise in the ongoing process. Further, in the case of the above-described embodiment with respect to FIG. 1, even though a period of multiple months may be required to determine the factor contributing to yield reduction, by determining the factors contributing to the yield reduction based on the data of the wafer that is within the semiconductor manufacturing process, the factors contributing to the yield reduction may be determined within a shorter period of time and responded to proactively.

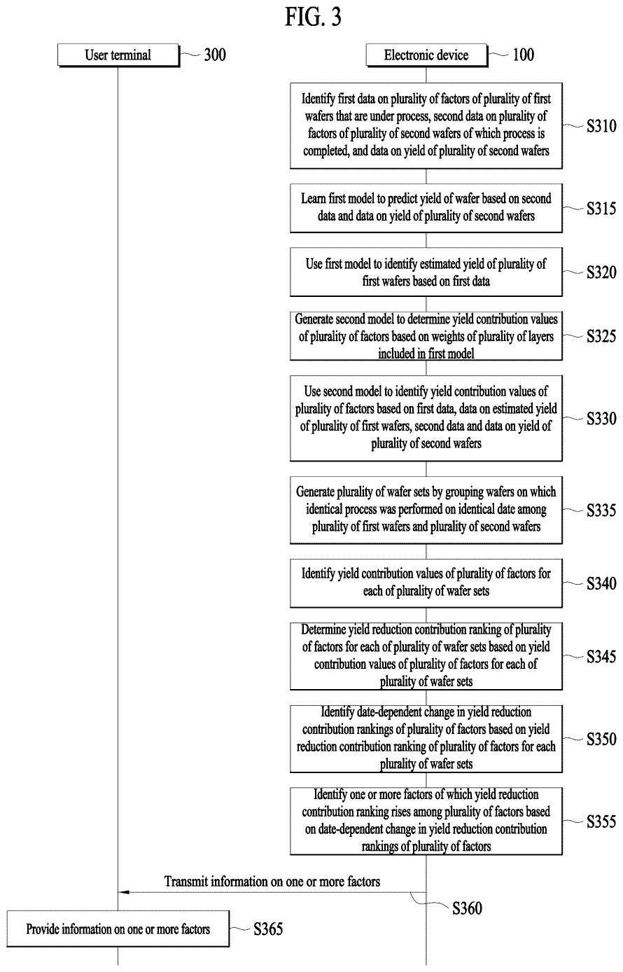

FIG. 3 is a flowchart of a method of an electronic device that provides information on factors contributing to yield reduction according to one or more embodiments.

In operation S310, according to an example embodiment, an electronic device 100 (e.g., any of the electronic devices 100 of FIGS. 1 and 2 and the electronic devices 1110 or 100 of FIGS. 11 and 12) may identify first data on a plurality of factors of a plurality of first wafers that are within (i.e., under) a semiconductor manufacturing process, second data on a plurality of factors of a plurality of second wafers of which the semiconductor manufacturing process has completed, and data on the yield of the plurality of second wafers. More specifically, the electronic device 100 may obtain category data for a plurality of equipment pieces used in the semiconductor manufacturing process of a plurality of first wafers, measurement data on a plurality of measurement items measured in the semiconductor manufacturing process of the plurality of first wafers, category data on the plurality of equipment pieces in the plurality of second wafers, measurement data on the plurality of measurement items of the plurality of second wafers and data on the yield of the plurality of second wafers.

For example, the electronic device 100 may identify one or more pieces of first equipment that have been used in the semiconductor manufacturing process of a plurality of first wafers that are within the semiconductor manufacturing process among a plurality of equipment pieces used in the semiconductor manufacturing process. Subsequently, the electronic device 100 may obtain the category data for the one or more pieces of first equipment of the plurality of first wafers from a database stored in a memory of the electronic device (e.g., stored in memory 1140 of the electronic device 1110 of FIG. 11 or memory 1200 of FIG. 12). For example, as the first wafers are being processed in the semiconductor manufacturing process such respective category information may be stored to the database.

In another example embodiment, the electronic device 100 may identify one or more pieces of second equipment that are predetermined (i.e., herein, according to a predetermined processing schedule set for each wafer and respective equipment) to be used in the semiconductor manufacturing process of a plurality of first wafers that are within the semiconductor manufacturing process among a plurality of equipment pieces used in the semiconductor manufacturing process. Subsequently, the electronic device 100 may identify the most recently obtained data for the one or more pieces of second equipment based on the semiconductor manufacturing process history on the one or more pieces of second equipment. The electronic device 100 may replace category data on the one or more pieces of second equipment that are predetermined to be used in the semiconductor manufacturing process of the plurality of first wafers with the most recently obtained data on one or more pieces of second equipment.

In another example embodiment, the electronic device 100 may identify one or more first measurement items that are measured with respect to the plurality of first wafers that are within the semiconductor manufacturing process among the plurality of measurement items that are measured in the semiconductor manufacturing process. Subsequently, the electronic device 100 may obtain measurement data on one or more first measurement items of the plurality of first wafers from a/the database stored in the memory of the electronic device (e.g., stored in memory 1140 of the electronic device 1110 of FIG. 11 or memory 1200 of FIG. 12). For example, as the first wafers are being processed in the semiconductor manufacturing process such respective first measurement items may be stored to the database.

In an example embodiment, the electronic device 100 may identify one or more second measurement items that are predetermined to be measured for a plurality of first wafers that are within the semiconductor manufacturing process among a plurality of measurement items measured in the semiconductor manufacturing process. Subsequently, based on the semiconductor manufacturing process history on the one or more second measurement items, the electronic device 100 may identify the most recently obtained data on the one or more second measurement items. The electronic device 100 may replace the measurement data for the one or more second measurement items of the plurality of first wafers that are predetermined to be used in the semiconductor manufacturing process with the most recently acquired data on one or more second measurement items.

In an example embodiment, from a/the database stored in the memory of the electronic device (e.g., stored in memory 1140 of the electronic device 1110 of FIG. 11 or memory 1200 of FIG. 12), the electronic device 100 may obtain category data on the plurality of equipment pieces in the plurality of second wafers, measurement data on the plurality of measurement items of the plurality of second wafers and data on the yield of the plurality of second wafers. For example, upon completion (or as the second wafter were being processed in the semiconductor manufacturing process) of each of the second wafers in the semiconductor manufacturing process such respective information may be stored to the database.

Here, the plurality of first wafers may indicate wafers for which the semiconductor manufacturing process will become completed within a first period of time based on a set date, and the plurality of second wafers may indicate wafers for which semiconductor manufacturing process has finished within a second period of time based on a set date. Alternatively, the plurality of first wafers and the plurality of second wafers may refer to wafers on which a specific process (among the respective processes of the semiconductor manufacturing process) has been performed within a third period of time based on a set date. However, the plurality of first wafers and the plurality of second wafers are not limited thereto.

In operation S315, according to an example embodiment, the electronic device 100 may train (i.e., learn) a first model to predict the yield of a wafer based on the second data and data on the yield of the plurality of second wafers. For example, as the first model, the electronic device 100 may generate an artificial intelligence (AI) model (e.g., a machine learning model) to predict the yield of a wafer through supervised, as a non-limiting example, machine learning in which a particular second data is set as input data and corresponding output data, on the yield of the plurality of second wafers, of the in-training AI model is compared to a label for the second data (e.g., as a correct output of the in-training AI model). As a non-limiting example, the AI model may include a neural network, and the machine learning may include gradient descent backpropagation performed based on a loss or error calculated based on many such comparisons for many second data.

In operation S320, according to an example embodiment, the electronic device 100 may use the first model to identify the estimated yield of the plurality of first wafers based on the first data. For example, the electronic device 100 may obtain data on estimated yield of the plurality of first wafers by inputting the first data on a plurality of factors of a plurality of first wafers that are within the semiconductor manufacturing process into the first model.

In operation S325, according to an example embodiment, the electronic device 100 may generate a second model to determine the yield contribution values of a plurality of factors based on parameters (e.g., weights) of a plurality of layers included in the first model (e.g., where the first model includes a neural network that includes at least the plurality of layers). For example, the electronic device 100 may analyze how much the weights learned in each of the plurality of layers included in the first model contribute to a specific part of the input data to generate an explainable artificial intelligence (XAI) model that outputs the yield contribution values of a plurality of factors.

Here, the second model may include a Shapley Additive exPlanations (SHAP) model or local interpretable model-agnostic explanations (LIME), but is not limited thereto. As a non-limiting example, the SHAP model may explain an output of any machine learning model, such as by assigning each feature a value representing its contribution to the prediction based on Shapley values from cooperative game theory (e.g., where Shapely values may show a distribution of prediction among features). As another non-limiting example, the LIME model may approximate a black box machine learning model with a local interpretable model to explain each individual prediction, such as to explain a prediction of any classifier in an interpretable and faithful manner by learning an interpretable model locally around the prediction. Further, a yield contribution value may be a numerical value that represents how a plurality of factors corresponding to each wafer contributed to the yield of that wafer. The yield contribution value may be referred to as the SHAP index, but is not limited to the above.

In operation S330, according to an example embodiment, the electronic device 100 may use the second model to identify the yield contribution values of a plurality of factors based on the first data, data on estimated yield of the plurality of first wafers, the second data and data on the yield of the plurality of second wafers. For example, when the electronic device 100 inputs the first data, the data on estimated yield of the plurality of first wafers, the second data and the data on the yield of the plurality of second wafers into the second model, the second model may measure a yield contribution value of each factor by identifying how the deviation of the input data from the average affects the deviation between the corresponding (expected) yield and the average.

Here, the yield contribution values may be determined based on the relative impact of a plurality of factors on the yield of a specific wafer. Accordingly, the sum of the yield contribution values of the plurality of factors corresponding to a wafer may be equal to the yield of the wafer. Further, the yield contribution value of a factor that contributes to an increase in yield may have a positive value, and the yield contribution value of a factor that contributes to a decrease in yield may have a negative value, but the present disclosure is not limited thereto.

In operation S335, the electronic device 100 may generate a plurality of wafer sets by grouping wafers on which the same process was performed on the same date among a plurality of first wafers and a plurality of second wafers, according to an example embodiment. For example, the electronic device 100 may generate a wafer set including a plurality of first wafers having the same expected semiconductor manufacturing process completion date. Further, the electronic device 100 may generate a wafer set including wafers with the same semiconductor manufacturing process completion date among a plurality of second wafers.

In operation S340, according to an example embodiment, the electronic device 100 may identify yield contribution values of a plurality of factors for each of the plurality of wafer sets. For example, the electronic device 100 may identify the yield contribution values of a first factor corresponding to wafers included in the first wafer set among a plurality of wafer sets. Subsequently, the electronic device 100 may determine the average value of the yield contribution values of the first factor corresponding to the wafer included in the first wafer set as the yield contribution value of the first factor for the first wafer set. In this manner, the electronic device 100 may determine the yield contribution values of a plurality of factors for each of the plurality of wafer sets.

In operation S345, according to an example embodiment, the electronic device 100 may determine yield reduction contribution rankings of the plurality of factors for each of the plurality of wafer sets based on the yield contribution values of the plurality of factors for each of the plurality of wafer sets. For example, the electronic device 100 may identify the yield contribution values of a plurality of factors for the first wafer set. Subsequently, the electronic device 100 may determine the yield reduction contribution rankings of a plurality of factors for the first wafer set by giving a higher rank to the factor with lower yield contribution value among the plurality of factors regarding the first wafer set.

In operation S350, according to an example embodiment, the electronic device 100 may identify date-dependent change in the yield reduction contribution rankings of the plurality of factors based on the yield reduction contribution ranking of a plurality of factors for each plurality of wafer sets. More specifically, the electronic device 100 may identify factors that are ranked at least a set number of times among a plurality of factors, and identify the date-dependent change in the yield reduction contribution rankings of the identified factors.

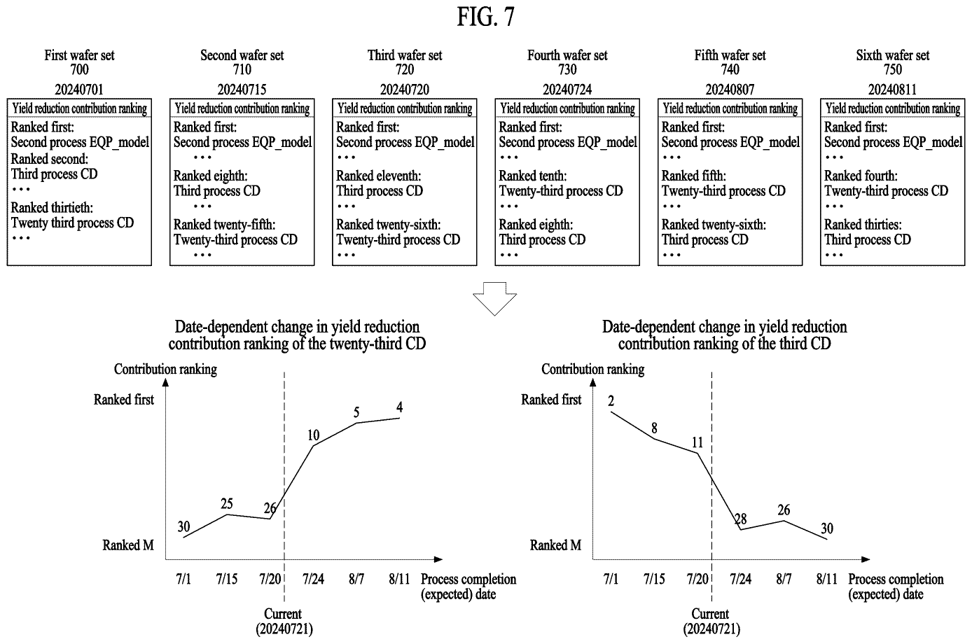

For example, the electronic device 100 may identify a yield reduction contribution ranking of the first factor for each of a plurality of wafer sets, and identify the change in yield reduction contribution ranking of the first factor according to semiconductor manufacturing process completion (expected) date corresponding to a plurality of wafer sets. In this manner, the electronic device 100 may identify date-dependent change in a yield reduction contribution ranking of each of the plurality of factors. This will be explained in detail with reference to FIG. 7.

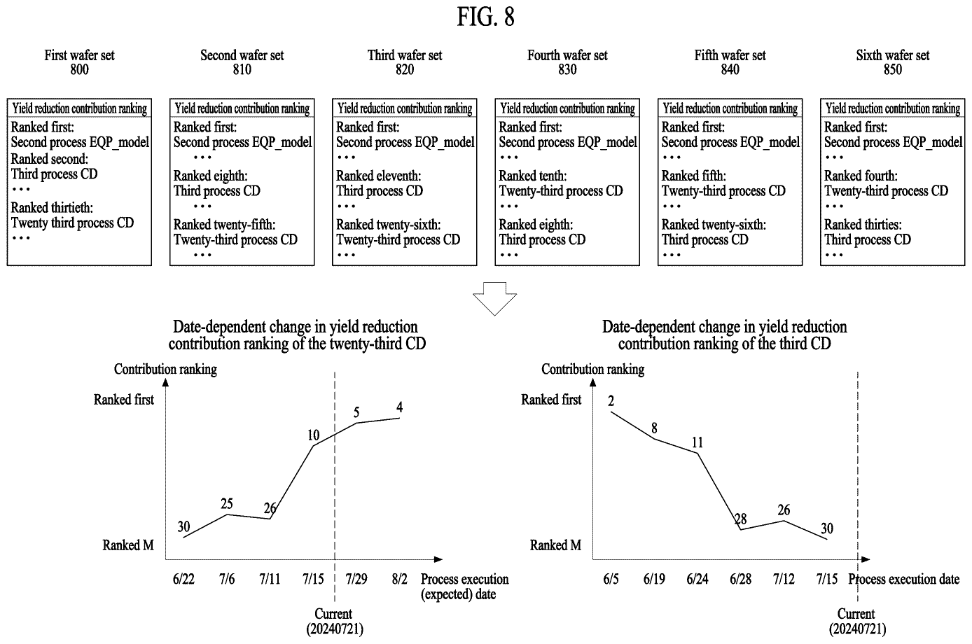

In an example embodiment, the electronic device 100 may identify the yield reduction contribution ranking of the first factor for each of a plurality of wafer sets, and identify the change in yield reduction contribution ranking of the first factor according to the date on which a process (among the processes of the semiconductor manufacturing process) corresponding to the first factor was (will be) performed for each of a plurality of wafer sets. In this manner, the electronic device 100 may identify the date-dependent change in the yield reduction contribution ranking of each plurality of factors. This will be explained in detail with reference to FIG. 8.

In operation S355, according to an example embodiment, among a plurality of factors, the electronic device 100 may identify one or more factors of which yield reduction contribution ranking rises based on the date-dependent change in yield reduction contribution rankings of the plurality of factors. For example, the electronic device 100 may identify the date-dependent change in yield reduction contribution rankings of the plurality of factors, and identify one or more factors with a rising yield reduction contribution ranking among a plurality of factors as factors contributing to yield reduction. Alternatively, the electronic device 100 may identify the date-dependent change in yield reduction contribution rankings of the plurality of factors, and determine that a factor whose yield reduction contribution ranking drops among a plurality of factors as a factor whose problem has been resolved due to a corresponding process having been improved.

In operation S360, according to an example embodiment, the electronic device 100 may transmit information on one or more factors to a user terminal 300. For example, the electronic device 100 may transmit, to the user terminal 300, at least one of information indicating the date-dependent change in the yield reduction contribution rankings of one or more factors, information on equipment corresponding to the one or more factors, and information corresponding to the measurement item corresponding to the one or more factors. As a non-limiting example, the user terminal 300 may correspond to the user terminal 1108 of FIG. 11.

In operation S365, according to an example embodiment, the user terminal 300 may provide the user with information on one or more factors. For example, based on information received from the electronic device 100, the user terminal 300 may display at least one of the information indicating the date-dependent change in the yield reduction contribution rankings of one or more factors, the information on equipment corresponding to the one or more factors, and the information corresponding to the measurement item corresponding to the one or more factors.

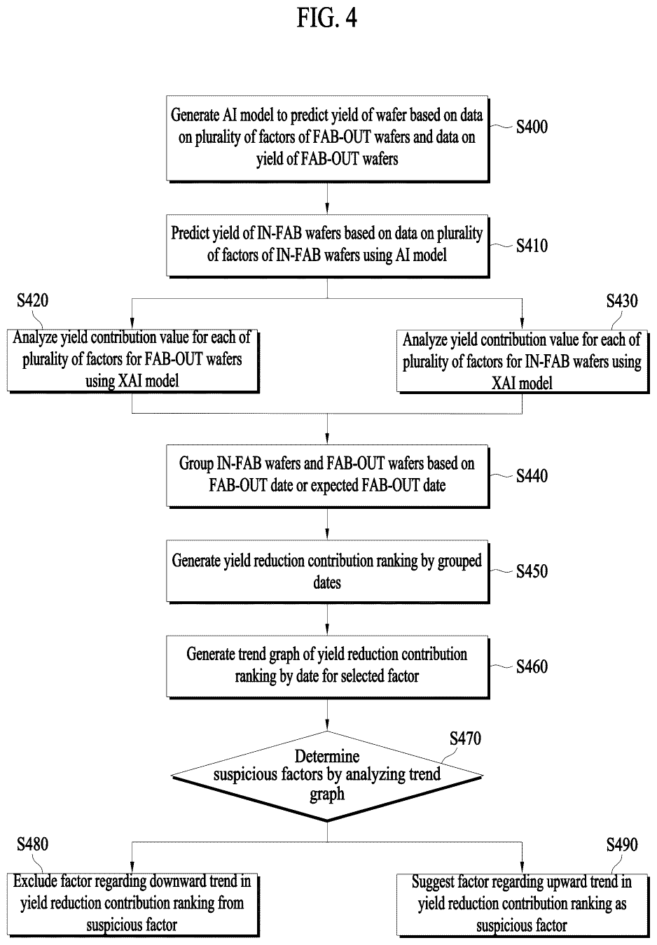

FIG. 4 is a flowchart of a method of an electronic device that provides information on factors contributing to yield reduction according to one or more embodiments. Example content that overlaps with the above content in relation to FIG. 3 may be briefly explained or omitted.

In operation S400, according to an example embodiment, an electronic device 100 (e.g., any of the electronic devices 100 of FIGS. 1 and 2 and the electronic devices 1110 or 100 of FIGS. 11 and 12) may generate an AI model (e.g., as described above with respect to FIG. 3) to predict the yield of a wafer based on data on the plurality of factors of FAB-OUT wafers and data on the yield of FAB-OUT wafers. For example, the electronic device 100 may generate the AI model to predict the yield of a wafer with supervised learning in which the data on the plurality of factors of FAB-OUT wafers is set as input data and the data on the yield of FAB-OUT wafers is set as answer data.

In operation S410, according to an example embodiment, the electronic device 100 may predict the yield of IN-FAB wafers based on data on the plurality of factors of the IN-FAB wafers using the AI model. For example, the electronic device 100 may obtain data on the estimated yield of IN-FAB wafers by inputting the data on the plurality of factors of the IN-FAB wafers into the AI model.

In operation S420, the electronic device 100 may analyze a yield contribution value for each of the plurality of factors for FAB-OUT wafers using an XAI model (e.g., as described above with respect to FIG. 3) according to an example embodiment. For example, the electronic device 100 may obtain yield contribution values of a plurality of factors by inputting data on a plurality of factors of FAB-OUT wafers and data on the yield of FAB-OUT wafers into the XAI model generated based on the AI model for predicting yield.

In operation S430, according to an example embodiment, the electronic device 100 may analyze a yield contribution value for each of the plurality of factors for IN-FAB wafers using the XAI model. For example, the electronic device 100 may obtain yield contribution values of a plurality of factors by inputting data on the plurality of factors of the IN-FAB wafers and data on the estimated yield of the IN-FAB wafers into the XAI model generated based on the AI model for predicting yield.

In operation S440, according to an example embodiment, the electronic device 100 may group IN-FAB wafers and FAB-OUT wafers based on FAB-OUT date or expected FAB-OUT date. For example, the electronic device 100 may group wafers with the same FAB-OUT date among FAB-OUT wafers, and group wafers among IN-FAB wafers that have the same expected FAB-OUT date. Alternatively, the electronic device 100 may group wafers that have undergone a specific process on the same date among FAB-OUT wafers, and group wafers that have undergone a specific process on the same date among IN-FAB wafers.

In operation S450, according to an example embodiment, the electronic device 100 may generate yield reduction contribution ranking by grouped dates. For example, the electronic device 100 may identify the yield contribution values by wafer with the same FAB-OUT date or the same expected FAB-OUT date, and identify the yield reduction contribution ranking by wafer with the same FAB-OUT date or the same expected FAB-OUT date based on the yield contribution values.

In operation S460, the electronic device 100 may generate a trend graph of yield reduction contribution ranking by date for a selected factor according to an example embodiment. For example, the electronic device 100 may select factors that are ranked at least a set rank or higher at least a set number of times among a plurality of factors. Subsequently, the electronic device 100 may generate a trend graph showing the date-dependent change in the yield reduction contribution rankings for selected factors.

In operation S470, the electronic device 100 may determine suspicious factors by analyzing a trend graph according to an example embodiment. For example, the electronic device 100 may exclude factors related to the downward trend in yield reduction contribution ranking from the suspicious factor, and determine the factor regarding the upward trend of yield reduction contribution ranking as a suspicious factor.

In operation S480, according to an example embodiment, the electronic device 100 may exclude a factor regarding a downward trend in yield reduction contribution ranking from suspicious factors. For example, the electronic device 100 may determine that factors related to trends in contribution rankings do not contribute to yield reduction, and may not provide information on that factor to the user.

In operation S490, according to an example embodiment, the electronic device 100 may suggest a factor regarding a upward trend in yield reduction contribution ranking as a suspicious factor. For example, the electronic device 100 may provide users with information on factors that contribute to yield reduction, as the electronic device 100 determines that factors with a rising yield reduction contribution ranking trend contribute to the yield reduction. For example, the electronic device 100 may provide the user with the information through a user terminal, such as the user terminal 1108 of FIG. 11.

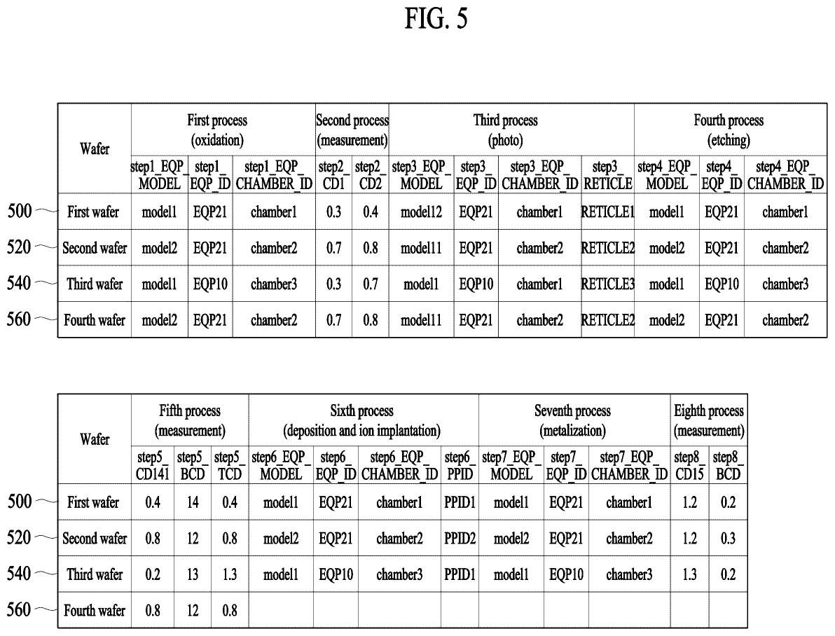

FIG. 5 illustrates an example of data for a plurality of factors related to a semiconductor manufacturing process according to one or more embodiments.

According to an example embodiment, an electronic device 100 (e.g., any of the electronic devices 100 of FIGS. 1 and 2 and the electronic device 1110 or 100 of FIGS. 11 and 12) may identify data on a plurality of factors related to a semiconductor manufacturing process of a semiconductor manufacturing process-finished wafer. More specifically, the electronic device 100 may obtain the category data for a plurality of equipment pieces used in the semiconductor manufacturing process of a semiconductor manufacturing process-finished wafer, and the measurement data for a plurality of measurement items that are measured in the semiconductor manufacturing process of a semiconductor manufacturing process-finished wafer.

For example, referring to FIG. 5, the electronic device 100 may obtain data on the equipment identification information (EQP_ID), the equipment model information (EQP_MODEL), the identification information of a chamber within the equipment (EQP_CHAMBER_ID), the process program identification (PPID) information (EQP_PPID), and the reticle information (EQP_RETICLE) used in the first process, the third process, the fourth process, the sixth process and the seventh process of a first wafer 500. Further, the electronic device 100 may obtain data on measurement items that are measured in the second process, fifth process, and eighth process of the first wafer 500.

In an example embodiment, referring to FIG. 5, the electronic device 100 may obtain data on equipment identification information, equipment model information, identification information of a chamber in the equipment, PPID information and reticle information used in the first process, the third process, the fourth process, the sixth process and the seventh process of a second wafer 520. The electronic device 100 may obtain data on measurement items that are measured in the second process, the fifth process and the eighth process of the second wafer 520.

In an example embodiment, referring to FIG. 5, the electronic device 100 may obtain data on equipment identification information, equipment model information, identification information of a chamber in the equipment, PPID information and reticle information used in the first process, the third process, the fourth process, the sixth process and the seventh process of a third wafer 540. Further, the electronic device 100 may obtain data on measurement items that are measured in the second process, the fifth process, and the eighth process of the third wafer 540.

According to an example embodiment, the electronic device 100 may identify data on factors corresponding to a process performed on a wafer that is within the semiconductor manufacturing process. More specifically, the electronic device 100 may obtain category data for one or more pieces of first equipment used in the processing of a wafer that is within the process, and measurement data for one or more first measurement items that are measured on a wafer that is within the process.

In an example embodiment, referring to FIG. 5, the electronic device 100 may obtain data on equipment identification information, equipment model information, identification information of a chamber in the equipment and reticle information used in the first process, the third process and the fourth process of a fourth wafer 560. Further, the electronic device 100 may obtain data on measurement items that are measured in the second process and the fifth process of the fourth wafer 560.

Meanwhile, the combination and order of the aforementioned processes, the factors for each process, and the specific data for the factors are only an example embodiment, and thus it would be apparent to a person skilled in the art that the present disclosure may be implemented with example embodiments different from those described above.

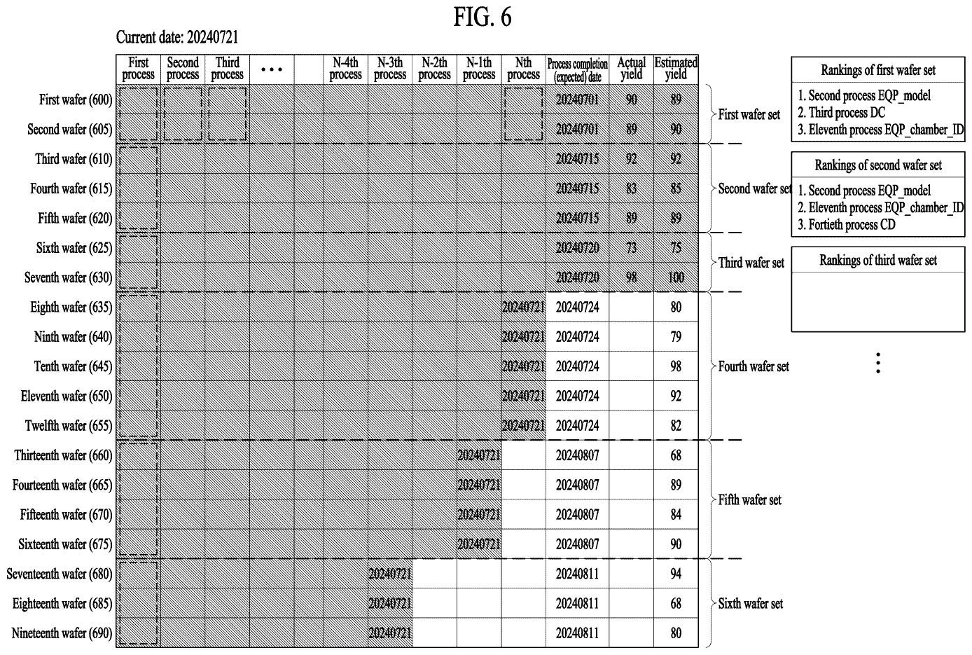

FIG. 6 illustrates a method of an electronic device for determining yield reduction contribution rankings of a plurality of factors for each of a plurality of wafer sets according to one or more embodiments. Example content that overlaps with the above-described content in relation to FIG. 3 may be briefly explained or omitted.

According to an example embodiment, an electronic device 100 (e.g., any of the electronic devices 100 of FIGS. 1 and 2 and the electronic device 1110 or 100 of FIG. 11 or 12) may identify data on a plurality of factors related to a semiconductor manufacturing process of a semiconductor manufacturing process-finished wafer. For example, referring to FIG. 6, the electronic device 100 may obtain data on factors corresponding n number of processes of each of a first wafer 600, a second wafer 605, a third wafer 610, a fourth wafer 615, a fifth wafer 620, a sixth wafer 625 and a seventh wafer 630 for which the semiconductor manufacturing process has completed.

According to an example embodiment, the electronic device 100 may identify data on the yield of the semiconductor manufacturing process-finished wafer. For example, referring to FIG. 6, the electronic device 100 may obtain data that the yields of the first wafer 600, the second wafer 605, the third wafer 610, the fourth wafer 615, the fifth wafer 620, the sixth wafer 625, and the seventh wafer 630 are 90, 89, 92, 83, 89, 73 and 98, respectively.

According to an example embodiment, the electronic device 100 may identify data on a plurality of factors related to the semiconductor manufacturing process of a wafer that is within the semiconductor manufacturing process. More specifically, the electronic device 100 may identify the processes of the semiconductor manufacturing process that have already been performed and the remaining processes of the semiconductor manufacturing process that will be performed in the future for a wafer that is within the semiconductor manufacturing process. Subsequently, the electronic device 100 may obtain data on factors corresponding to the processes that have already been performed, and generate substitute (imputation) data for factors corresponding to a process of the semiconductor manufacturing process that is predetermined to be performed in the future.

For example, referring to FIG. 6, the electronic device 100 may identify n-1 number of processes are performed on an eighth wafer 635, a ninth wafer 640, a tenth wafer 645, an eleventh wafer 650, and a twelfth wafer 655, which are in the semiconductor manufacturing process. Subsequently, the electronic device 100 may obtain data for factors corresponding to n-1 number of processes of each of the eighth wafer 635, the ninth wafer 640, the tenth wafer 645, the eleventh wafer 650 and the twelfth wafer 655, and generate substitute data for factors corresponding to the nth process of each of the eighth wafer 635, the ninth wafer 640, the tenth wafer 645, the eleventh wafer 650 and the twelfth wafer 655.

In an example embodiment, for example, referring to FIG. 6, the electronic device 100 may identify that n-2 number of processes are performed on a thirteenth wafer 660, a fourteenth wafer 665, a fifteenth wafer 670 and a sixteenth wafer 675, which are in the semiconductor manufacturing process. Subsequently, the electronic device 100 may obtain data for factors corresponding to n-2 number of processes of each of the thirteenth wafer 660, the fourteenth wafer 665, the fifteenth wafer 670 and the sixteenth wafer 675, and the electronic device 100 may generate substitute data for factors corresponding to the n-1th process and the nth process of each of the thirteenth wafer 660, the fourteenth wafer 665, the fifteenth wafer 670 and the sixteenth wafer 675.

In an example embodiment, referring to FIG. 6, the electronic device 100 may identify that n-4 number of processes have been performed on a seventeenth wafer 680, an eighteenth wafer 685, and a nineteenth wafer 690, which are in the semiconductor manufacturing process. Subsequently, the electronic device 100 may obtain data for factors corresponding to n-4 number of processes of each of the seventeenth wafer 680, the eighteenth wafer 685 and the nineteenth wafer 690, and generate substitute data for factors corresponding to the n-3th process to the nth process of each of the seventeenth wafer 680, the eighteenth wafer 685 and the nineteenth wafer 690.

According to an example embodiment, the electronic device 100 may use a first model (e.g., an AI model described above with respect to FIGS. 3-4) to predict the yield of a wafer and identify the estimated yield of the wafer that is within the semiconductor manufacturing process. More specifically, the electronic device 100 may obtain the estimated yield of a wafer that is within the semiconductor manufacturing process by inputting data on a plurality of factors of the wafer that is within the semiconductor manufacturing process into the first model.

For example, referring to FIG. 6, the electronic device 100 may generate the AI model to predict the yield of a wafer based on data for a plurality of factors of each of the first wafer 600, the second wafer 605, the third wafer 610, the fourth wafer 615, the fifth wafer 620, the sixth wafer 625 and the seventh wafer 630 and data for yield of each of the first wafer 600, the second wafer 605, the third wafer 610, the fourth wafer 615, the fifth wafer 620, the sixth wafer 625 and the seventh wafer 630. Subsequently, by entering data for a plurality of factors of each of the eighth wafer 635, the ninth wafer 640, the tenth wafer 645, the eleventh wafer 650, the twelfth wafer 655, the thirteenth wafer 660, the fourteenth wafer 665, the fifteenth wafer 670, the sixteenth wafer 675, the seventeenth wafer 680, the eighteenth wafer 685 and the nineteenth wafer 690 into the AI model, the electronic device 100 may obtain data that the estimated yields of the eighth wafer 635, the ninth wafer 640, the tenth wafer 645, the eleventh wafer 650, the twelfth wafer 655, the thirteenth wafer 660, the fourteenth wafer 665, the fifteenth wafer 670, the sixteenth wafer 675, the seventeenth wafer 680, the eighteenth wafer 685 and the nineteenth wafer 690 are 80, 79, 98, 92, 82, 68, 89, 84, 90, 94, 68 and 80, respectively.

According to an example embodiment, the electronic device 100 may identify yield contribution values of a plurality of factors using a second model generated based on the first model. For example, referring to FIG. 6, by inputting data on the plurality of factors of the first wafer 600 to the nineteenth wafer 690, data on the yield of the first wafer 600 to the seventh wafer 630, and data on the estimated yield of the eighth wafer 635 to the nineteenth wafer 690 into the second model as an XAI model (e.g., as described above with respect to FIGS. 3-4) to determine the yield contribution values of the plurality of factors, the electronic device 100 may obtain yield contribution values of the plurality of factors for each of the first wafer 600 to the nineteenth wafer 690.

According to an example embodiment, the electronic device 100 may generate a plurality of wafer sets by grouping wafers with the same semiconductor manufacturing process completion (expected) date among process-finished wafers and wafers that are within the semiconductor manufacturing process.

For example, referring to FIG. 6, the electronic device 100 may generate a first wafer set by grouping the first wafer 600 and the second wafer 605, which have the same semiconductor manufacturing process completion date of the example 2024 Jul. 1.

According to an example embodiment, referring to FIG. 6, the electronic device 100 may generate a second wafer set by grouping the third wafer 610, the fourth wafer 615 and the fifth wafer 620, which have the same semiconductor manufacturing process completion date of the example 2024 Jul. 15.

According to an example embodiment, referring to FIG. 6, the electronic device 100 may generate a third wafer set by grouping the sixth wafer 625 and the seventh wafer 630, which have the same semiconductor manufacturing process completion date of the example 2024 Jul. 20.

According to an example embodiment, referring to FIG. 6, the electronic device 100 may generate a fourth wafer set by grouping the eighth wafer 635, the ninth wafer 640, the tenth wafer 645, the eleventh wafer 650 and the twelfth wafer 655, which have the same expected semiconductor manufacturing process completion date of the example 2024.07.24.

According to an example embodiment, referring to FIG. 6, the electronic device 100 may generate a fifth wafer set by grouping the thirteenth wafer 660, the fourteenth wafer 665, the fifteenth wafer 670 and the sixteenth wafer 675, which have the same expected semiconductor manufacturing process completion date of 2024 Aug. 7.

According to an example embodiment, referring to FIG. 6, the electronic device 100 may generate a sixth wafer set by grouping the seventeenth wafer 680, the eighteenth wafer 685 and the nineteenth wafer 690, which have the same expected semiconductor manufacturing process completion date of the example 2024 Aug. 11.

According to an example embodiment, the electronic device 100 may identify yield contribution values of a plurality of factors for each of a plurality of wafer sets. For example, the electronic device 100 may determine the average value of the yield contribution values of a first factor corresponding to the first wafer 600 and the second wafer 605 included in the first wafer set as the yield contribution value of the first factor for the first wafer set. In the same manner, the electronic device 100 may determine the yield contribution values of a plurality of factors for each of the first wafer set to the sixth wafer set.

According to an example embodiment, the electronic device 100 may determine yield reduction contribution rankings of the plurality of factors for each of the plurality of wafer sets based on yield contribution values of a plurality of factors for each of the plurality of wafer sets.

In an example embodiment, referring to FIG. 6, the electronic device 100 may identify that the yield contribution value of the second process EQP_model is the lowest, followed by the third process CD and the 11th process EQP_chamber_ID, based on the yield contribution values of a plurality of factors for the first wafer set. Accordingly, the electronic device 100 may determine the ranks of the second process EQP_model, the third process CD and the 11th process EQP_chamber_ID for the first wafer set as 1st, 2nd and 3rd, respectively.

In an example embodiment, referring to FIG. 6, the electronic device 100 may identify that the yield contribution value of the second process EQP_model is the lowest, followed by the 11th process EQP_chamber_ID and the 40th process CD, based on the yield contribution values of a plurality of factors for the second wafer set. Accordingly, the electronic device 100 may determine the ranks of the second process EQP_model, the 11th process EQP_chamber_ID and the 40th process CD for the first wafer set as 1st, 2nd and 3rd, respectively.

Meanwhile, the specific data on the aforementioned plurality of factors, data on yield, and data on estimated yield are only an example embodiment, and thus it would be apparent to a person skilled in the art that the present disclosure may be implemented with example embodiments different from those described above.

FIG. 7 illustrates a method of an electronic device for determining factors contributing to yield reduction according to one or more embodiments. Example content that overlaps with the above-described content in relation to FIG. 3 may be briefly explained or omitted.

According to an example embodiment, an electronic device 100 (e.g., any of the electronic devices 100 of FIGS. 1 and 2 and the electronic devices 1110 or 100 of FIGS. 11 and 12) may generate a graph showing date-dependent change in yield reduction contribution rankings of the plurality of factors, based on the yield reduction contribution rankings of a plurality of factors for each plurality of wafer sets.

According to an example embodiment, referring to FIG. 7, the electronic device 100 may identify that the yield reduction contribution ranking of the 23rd process CD for a first wafer set 700 is 30th, the yield reduction contribution ranking of the 23rd process CD for a second wafer set 710 is 25th, and the yield reduction contribution ranking of the 23rd process CD for a third wafer set 720 is 26th. Further, the electronic device 100 may identify that the yield reduction contribution ranking of the 23rd process CD for a fourth wafer set 730 is 10th, and the yield reduction contribution ranking of the 23rd process CD for a fifth wafer set 740 is 5th, and the yield reduction contribution ranking of the 23rd process CD for a sixth wafer set 750 is 4th. Identifying that the 23rd process CD ranks 15th or higher three times or more, the electronic device 100 may generate a graph showing the change in yield reduction contribution ranking of the 23rd process CD according to the semiconductor manufacturing process completion dates of the first wafer set 700, the second wafer set 710 and the third wafer set 720 and the expected semiconductor manufacturing process completion dates of the fourth wafer set 730, the fifth wafer set 740 and the sixth wafer set 750.

According to an example embodiment, referring to FIG. 7, the electronic device 100 may identify that the yield reduction contribution ranking of third process CD for the first wafer set 700 is 2nd, and the yield reduction contribution ranking of third process CD for the second wafer set 710 is 8th, and the yield reduction contribution ranking of third process CD for the third wafer set 720 is 11th. Further, the electronic device 100 may identify that the yield reduction contribution ranking of third process CD for the fourth wafer set 730 is 28th, and the yield reduction contribution ranking of third process CD for the fifth wafer set 740 is 26th, and the yield reduction contribution ranking of third process CD for the sixth wafer set 750 is 30th. Identifying that the third process CD ranked 15th or higher three times or more, the electronic device 100 may generate a graph showing the change in yield reduction contribution ranking of the third process CD according to the semiconductor manufacturing process completion dates of the first wafer set 700, the second wafer set 710 and the third wafer set 720, and the expected semiconductor manufacturing process completion dates of the fourth wafer set 730, the fifth wafer set 740 and the sixth wafer set 750.

According to an example embodiment, the electronic device 100 may identify one or more factors whose yield reduction contribution ranking rises among the plurality of factors based on the date-dependent change in yield reduction contribution rankings of the plurality of factors.

In an example embodiment, the electronic device 100 may identify that based on the graph showing the change in yield reduction contribution ranking of process 23 CD, the yield reduction contribution ranking of process 23 CD rises. Accordingly, the electronic device 100 may identify the 23rd process CD as a factor contributing to yield reduction, in other words, a factor to which the corresponding process (i.e., the 23^{rd} process CD) of the semiconductor manufacturing process should be improved.

In an example embodiment, based on the graph showing the change in yield reduction contribution ranking of the third process CD, the electronic device 100 may identify that the yield reduction contribution ranking of the third process CD is decreasing. Accordingly, the electronic device 100 may determine that the third process CD is a factor of which a problem has been solved due to a corresponding process improvement.

Meanwhile, the specific plurality of factors and yield reduction contribution ranking of plurality of factors described above are only example embodiments, and thus it would be apparent to a person skilled in the art that the present disclosure may be implemented with example embodiments different from those described above.

FIG. 8 illustrates a method of an electronic device for determining factors contributing to yield reduction according to one or more embodiments. Example content that overlaps with the above-described content in relation to FIG. 3 may be briefly explained or omitted.

According to an example embodiment, an electronic device 100 (e.g., any of the electronic devices 100 of s. 1 and 2 and the electronic device 1110 or 100 of FIGS. 11 and 12) may generate a graph showing date-dependent change in yield reduction contribution rankings of the plurality of factors, based on the yield reduction contribution ranking of a plurality of factors for each plurality of wafer sets.

In an example embodiment, referring to FIG. 8, the electronic device 100 may identify that the yield reduction contribution ranking of the 23rd process CD for a first wafer set 800 is 30th, the yield reduction contribution ranking of the 23rd process CD for a second wafer set 810 is 25th, and the yield reduction contribution ranking of the 23rd process CD for a third wafer set 820 is 26th. Further, the electronic device 100 may identify that the yield reduction contribution ranking of the 23rd process CD for a fourth wafer set 830 is 10th, and the yield reduction contribution ranking of the 23rd process CD for a fifth wafer set 840 is 5th, and the yield reduction contribution ranking of the 23rd process CD for a sixth wafer set 850 is 4th. Identifying that the 23rd process CD ranks 15th or higher three times or more, the electronic device 100 may generate a graph showing the change in yield reduction contribution ranking of the 23rd process CD according to date on which the 23rd process was performed for the first wafer set 800, the second wafer set 810, the third wafer set 820 and the fourth wafer set 830 and expected date on which the 23rd process to be executed for the fifth wafer set 840 and the sixth wafer set 850.

According to an example embodiment, referring to FIG. 8, the electronic device 100 may identify that the yield reduction contribution ranking of third process CD for the first wafer set 800 is 2nd, the yield reduction contribution ranking of third process CD for the second wafer set 810 is 8th, and the yield reduction contribution ranking of third process CD for the third wafer set 820 is 11th. Further, the electronic device 100 may identify that the yield reduction contribution ranking of the third process CD for the fourth wafer set 830 is 28th, the yield reduction contribution ranking of third process CD for the fifth wafer set 840 is 26th, and the yield reduction contribution ranking of third process CD for the sixth wafer set 850 is 30th. Identifying that the third process CD ranked 15th or higher three times or more, the electronic device 100 may generate a graph showing the change in yield reduction contribution ranking of the third process CD on the date the third process was performed for the first wafer set 800, the second wafer set 810, the third wafer set 820, the fourth wafer set 830, the fifth wafer set 840 and the sixth wafer set 850.

According to an example embodiment, the electronic device 100 may identify one or more factors whose yield reduction contribution rankings are rising among a plurality of factors, based on the date-dependent change in yield reduction contribution rankings of the plurality of factors.

In an example embodiment, the electronic device 100 may identify that the yield reduction contribution ranking of the 23rd process CD is rising based on the graph showing the change in yield reduction contribution ranking of the 23rd process CD. Accordingly, the electronic device 100 may identify the 23rd process CD as a factor contributing to yield reduction, in other words, as a factor to which a corresponding process (i.e., the 23^{rd} process CD) of the semiconductor manufacturing process should be improved.

In an example embodiment, the electronic device 100 may identify that the yield reduction contribution ranking of the third process CD is decreasing based on the graph showing the change in yield reduction contribution ranking of third process CD. Accordingly, the electronic device 100 may determine the third process CD as a factor of which a problem has been resolved due to a corresponding process improvement.

Meanwhile, the specific plurality of factors and yield reduction contribution ranking of plurality of factors described above are only example embodiments, and thus it would be apparent to a person skilled in the art that the present disclosure may be implemented with example embodiments different from those described above.

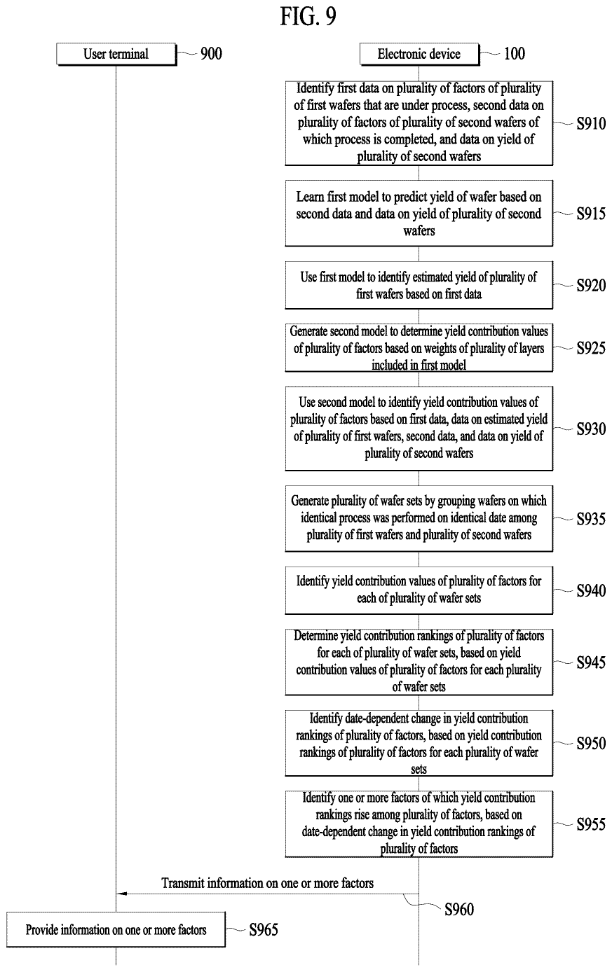

FIG. 9 is a flowchart of a method of an electronic device for providing information on factors contributing to yield reduction according to one or more embodiments. Example content that overlaps with the above-described content in relation to FIG. 3 may be briefly explained or omitted.

In operation S910, according to an example embodiment, an electronic device 100 (e.g., any of the electronic devices 100 of FIGS. 1 and 2 and the electronic devices 1110 or 100 of FIGS. 11 and 12) may identify first data on a plurality of factors of a plurality of first wafers that are within the semiconductor manufacturing process, second data on the plurality of factors of a plurality of second wafers of which process is completed, and data on the yield of the plurality of second wafers. For example, the electronic device 100 may obtain category data for a plurality of equipment pieces used in the semiconductor manufacturing process of a plurality of first wafers, measurement data on a plurality of measurement items measured in the semiconductor manufacturing process of the plurality of first wafers, category data on the plurality of equipment pieces in the plurality of second wafers, measurement data on the plurality of measurement items of the plurality of second wafers, and data on the yield of the plurality of second wafers.

In operation S915, according to an example embodiment, the electronic device 100 may learn a first model (e.g., an AI model, such as described above with respect to FIGS. 3-8) to predict the yield of a wafer based on second data and data on the yield of the plurality of second wafers. For example, the electronic device 100 may generate an AI model (e.g., as described above with respect to FIG. 3) to predict the yield of wafer through supervised learning with setting the second data as input data and data on the yield of the plurality of second wafers as answer data.

In operation S920, according to an example embodiment, the electronic device 100 may use the first model to identify the estimated yield of a plurality of first wafers based on the first data. For example, by inputting the first data on the plurality of factors of the plurality of first wafers that are within the semiconductor manufacturing process into the first model, the electronic device 100 may obtain data on the estimated yield of a plurality of first wafers.

In operation S925, according to an example embodiment, the electronic device 100 may generate a second model to determine yield contribution values of a plurality of factors based on parameters (e.g., weights) of a plurality of layers included in the first model (e.g., where the first model includes a neural network that includes at least the plurality of layers). For example, by analyzing how much the weights learned in each of the plurality of layers included in the first model contribute to a specific part of the input data, the electronic device 100 may generate the second model as an XAI model (e.g., as described above with respect to FIGS. 3-8) that outputs the yield contribution values of the plurality of factors.

In operation S930, according to an example embodiment, the electronic device 100 may use the second model to identify the yield contribution values of the plurality of factors based on first data, data on estimated yield of the plurality of first wafers, second data, and data on the yield of the plurality of second wafers. For example, when the electronic device 100 inputs the first data, the data on estimated yield of the plurality of first wafers, the second data, and the data on the yield of the plurality of second wafers to the second model, yield contribution value of each factor may be measured by the second model identifying how the deviation of the input data from the average affects the deviation between the corresponding (expected) yield and the average.

In operation S935, according to an example embodiment, the electronic device 100 may generate a plurality of wafer sets by grouping wafers on which identical process was performed on identical dates among a plurality of first wafers and a plurality of second wafers. For example, the electronic device 100 may generate a wafer set including a plurality of wafers having the same expected semiconductor manufacturing process completion date among the plurality of first wafers. Further, the electronic device 100 may generate a wafer set including a plurality of wafers having the same semiconductor manufacturing process completion date among the plurality of second wafers.

In operation S940, according to an example embodiment, the electronic device 100 may identify the yield contribution values of a plurality of factors for each of the plurality of wafer sets. For example, the electronic device 100 may identify the yield contribution values of a first factor corresponding to wafers included in the first wafer set among a plurality of wafer sets. Subsequently, the electronic device 100 may determine the absolute average value of the yield contribution values of the first factor corresponding to the wafers included in the first wafer set as the yield contribution of the first factor for the first wafer set. In the same manner, the electronic device 100 may determine yield contribution values of a plurality of factors for each of the plurality of wafer sets.

In operation S945, according to an example embodiment, the electronic device 100 may determine yield contribution rankings of a plurality of factors for each of a plurality of wafer sets, based on yield contribution values of the plurality of factors for each plurality of wafer sets. For example, the electronic device 100 may identify yield contribution values of a plurality of factors for the first wafer set. Subsequently, by giving a higher rank to the factor with higher yield contribution value among the plurality of factors regarding the first wafer set, the electronic device 100 may determine yield contribution rankings of the plurality of factors for the first wafer set.

In operation S950, according to an example embodiment, the electronic device 100 may identify date-dependent change in yield contribution rankings of the plurality of factors, based on the yield contribution rankings of the plurality of factors for each plurality of wafer sets. For example, the electronic device 100 may identify factors that are ranked at a set rank or higher at least a set number of times or more among a plurality of factors, and identify the date-dependent change in the yield contribution rankings of the identified factors.

In operation S955, according to an example embodiment, among a plurality of factors, the electronic device 100 may identify one or more factors of which yield contribution rankings rises based on the date-dependent change in yield contribution rankings of the plurality of factors. For example, the electronic device 100 may identify the date-dependent change in the yield contribution rankings of the plurality of factors, and identify one or more factors whose yield contribution rankings among a plurality of factors as factors of which influence on yield is increasing. Alternatively, the electronic device 100 may identify the change date-dependent change in the yield contribution rankings of the plurality of factors, and may determine that among the plurality of factors, a factor whose yield contribution ranking drops is a factor whose problem was resolved due to a corresponding process improvement.

In operation S960, according to an example embodiment, the electronic device 100 may transmit information on one or more factors to a user terminal 900. As a non-limiting example, the user terminal 900 may correspond to the user terminal 1108 of FIG. 11. For example, the electronic device 100 may transmit to the user terminal 900 at least one of information indicating date-dependent changes in the yield contribution rankings of one or more factors, information on equipment corresponding to the one or more factors, and information corresponding to the measurement item corresponding to the one or more factors.

In operation S965, according to an example embodiment, the user terminal 900 may provide the user with information on one or more factors. For example, based on the information received from the electronic device 100, the user terminal 900 may display at least one of the information indicating date-dependent changes in the yield contribution rankings of one or more factors, the information on equipment corresponding to the one or more factors, and the information corresponding to the measurement item corresponding to the one or more factors on a display.

In this way, by identifying information on factors affecting yield, the electronic device may identify whether a factor is a factor that increases or decreases yield.

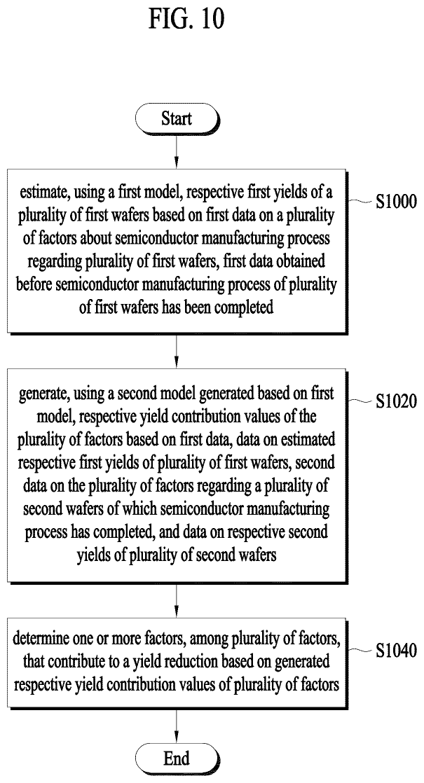

FIG. 10 illustrates a method according to one or more embodiments. The above descriptions of FIGS. 1-9 may be applied with respect to FIG. 10, and thus overlapping content may be omitted.

In operation S1000, using a first model (e.g., an AI model, such as described above with respect to FIGS. 3-9), the electronic device may estimate respective first yields of a plurality of first wafers based on first data on a plurality of factors about the semiconductor manufacturing process regarding the plurality of first wafers, the first data obtained before the semiconductor manufacturing process of the plurality of first wafers has been completed.

According to an example embodiment, a plurality of factors may include factors relating to a plurality of equipment pieces used in a semiconductor manufacturing process and factors relating to a plurality of measurement items measured in the semiconductor manufacturing process. Data, among the first data, regarding one wafer of the plurality of first wafers may include category data on one or more pieces of first equipment used among the plurality of equipment pieces in a first process of the semiconductor manufacturing process performed with respect to the one wafer, category data on one or more pieces of second equipment predetermined among the plurality of equipment pieces to be used in a second process of the semiconductor manufacturing process with respect to the one wafer, measurement data on one or more first measurement items, among the plurality of measurement items, that have been measured with respect to the one wafer in the semiconductor manufacturing process, and measurement data on one or more second measurement items, among the plurality of measurement items, predetermined to be measured with respect to the first wafer in the semiconductor manufacturing process. Another data, among the second data, regarding another one wafer of the plurality of second wafers may include category data on the plurality of equipment pieces with respect to the other one wafer and measurement data on the plurality of measurement items with respect to the other one wafer.

According to an example embodiment, the category data on one or more pieces of second equipment may include corresponding data obtained based on process history of the one or more pieces of second equipment, and the measurement data on one or more second measurement items may include corresponding data obtained based on process history of one or more second measurement items.

In operation S1020, using a second model (e.g., an XAI model, such as described above with respect to FIGS. 3-9) generated based on the first model, the electronic device may identify the yield contribution values of a plurality of factors based on the first data, data on estimated yield of the plurality of first wafers, second data on the plurality of factors of the plurality of second wafers of which process (among the processes of the semiconductor manufacturing process) is completed and data on the yield of the plurality of second wafers.

According to an example embodiment, the electronic device may generate the second model based on parameters (e.g., weights) of the plurality of layers included in the first model (e.g., where the first model includes a neural network that includes at least the plurality of layers), where the second model comprises an explainable artificial intelligence (XAI) model.

In operation S1040, the electronic device may determine one or more factors contributing to yield reduction among a plurality of factors based on the yield contribution values of the plurality of factors.

According to an example embodiment, the electronic device may train the first model based on the second data and the data on the respective second yields of the plurality of second wafers.

According to an example embodiment, when determining one or more factors that contribute to the yield reduction, the electronic device may identify date-dependent changes in respective yield reduction contribution rankings of the plurality of factors, based on the generated respective yield contribution values of the plurality of factors, and may identify, as the determined one or more factors that contribute to the yield reduction, corresponding one or more factors, among the plurality of factors, of which the respective yield reduction contribution rankings rise based on the date-dependent changes in the respective yield reduction contribution rankings of the plurality of factors.

According to an example embodiment, when identifying the date-dependent changes in the respective yield reduction contribution rankings of the plurality of factors, the electronic device may generate a plurality of wafer sets by grouping wafers for which an identical process (among the processes of the semiconductor manufacturing process) was performed on an identical date among a plurality of first wafers and a plurality of second wafers, identify the generated respective yield contribution values of a plurality of factors for each of a plurality of wafer sets, and determine a respective yield reduction contribution ranking of the plurality of factors for each of the plurality of wafer sets based on the identified generated respective yield contribution values.

According to an example embodiment, yield reduction contribution ranking of a first factor for the first wafer set among the respective yield reduction contribution rankings of the plurality of factors for each plurality of wafer sets may include one of a yield reduction contribution ranking corresponding to the date on which a first process (among the processes of the semiconductor manufacturing processes) corresponding to the first factor is executed on the first wafer set, a yield reduction contribution ranking corresponding to the date on which a second process corresponding to the first factor predetermined to be executed for the first wafer set, a yield reduction contribution ranking corresponding to the semiconductor manufacturing completion date of the first wafer set with respect to the semiconductor manufacturing process and a yield reduction contribution ranking corresponding to the expected semiconductor manufacturing completion date of the first wafer set with respect to the semiconductor manufacturing process.

According to an example embodiment, the determined respective yield reduction contribution rankings of the plurality of factors for a first wafer set, among the determined respective yield reduction contribution rankings of the plurality of factors for each of the plurality of wafer sets may be determined to be higher as the yield contribution values of the plurality of factors for the first wafer set are lower.

According to an example embodiment, the identified generated respective yield contribution values of the first factor for the first wafer set, among the identified generated respective yield contribution values of the plurality of factors for each of the plurality of wafer sets, may be determined as the average value of the generated respective yield contribution values of the first factor corresponding to the wafers included in the first wafer set.

According to an example embodiment, the plurality of first wafers may include wafers for which the semiconductor manufacturing process is set to be completed within a first period of time based on a set date, and the plurality of second wafers may include wafers for which the semiconductor manufacturing process is completed within a second period of time from a set date.

According to an example embodiment, the electronic device may provide the user terminal with information on determined one or more factors, and the information on determined one or more factors may include at least one of information indicating the date-dependent change in the yield reduction contribution rankings of determined one or more factors, information on equipment corresponding to the one or more factors, and information corresponding to the measurement item corresponding to the determined one or more factors.

FIG. 11 illustrates a semiconductor system with an electronic device according to one or more embodiments.

According to an example embodiment, an electronic device 1110 may include a transceiver 1120 (i.e., one or more transceivers 1120), a memory 1140 (i.e., one or more memories 1140), and a processor 1160 (i.e., one or more processors 1160). It should be understood by those skilled in the art related to the present embodiment that other and/or additional general components may be included in addition to the components illustrated in the electronic device 1110 (as well as the semiconductor system 1100) of FIG. 11. In an example embodiment, the transceiver 1120 may be included in a communication device of (or connected to, within the semiconductor system 1100) the electronic device 1110. Further, in an example embodiment, the processor 1160 may be included in a controller. The electronic device 1110 may correspond to the electronic device 100 of FIG. 12.

The transceiver 1120 may communicate (through wired/wireless communication) with external electronic devices. The external electronic device may be a terminal or a server. For example, the terminal may be the user terminal 1108 of the semiconductor system 1100 of FIG. 11) Additionally, communication technologies implemented by the transceiver 1120 may include global system for mobile communication (GSM), code division multi access (CDMA), long term evolution (LTE), 5G, wireless LAN (WLAN), wireless-fidelity (Wi-Fi), Bluetooth™, radio frequency identification (RFID), infrared data association (IrDA), ZigBee, and/or near field communication (NFC), as non-limiting examples.

The processor 1160 may control the overall operation of the electronic device 1110 and process data and signals. Further, the processor 1160 may execute code stored in the memory 1140, which when executed by the processor 1160 may configure the processor 1160 to perform any combination of operations described herein with respect to any of the electronic devices described herein. The processor 1160 is also representative of memory included in the processor 1160, which the processor 1160 may utilize to perform the operations described herein and control the overall operation of the electronic device 1110 and process data and signals by executing the code stored in memory further represented by the processor 1160 and/or the memory 1140.

Using a first machine learning model, the processor 1160 may identify an estimated yield of a plurality of first wafers based on first data on a plurality of factors regarding a semiconductor manufacturing process of a plurality of first IN-FAB wafers for which the semiconductor manufacturing process has not yet completed (i.e., wafters within the semiconductor manufacturing process). Using a second explainable artificial intelligence (XAI) model that is generated (e.g., by the processor 1160) based on the first machine learning model, the processor 1160 may identify yield contribution values of a plurality of factors based on first data, data on estimated yield of the plurality of first wafers, second data on the plurality of factors of the plurality of second wafers of which the semiconductor manufacturing process has completed and second data on the plurality of factors of the plurality of second wafers of which the semiconductor manufacturing process has completed. The processor 1160 may determine one or more factors contributing to yield reduction among the plurality of factors based on the yield contribution values of the plurality of factors.

The electronic device 1110 may further include a user interface device such as a hardware interface 1180 (e.g., a communication port, a touch panel, a display, key(s), and/or other button(s) for controlling the processor) that outputs any of the above described identified factors or information on (or dependent on) such one or more factors (e.g., corresponding to operations S365 or S965 of FIGS. 3 and 9) to a user, another application or program the electronic device 1110 is configured to execute, and/or an exterior device, and/or that communicates with the external device in addition to or in combination with operations of the transceiver 1120. As a non-limiting example, the external device may be a user terminal 1108 (e.g., in addition or as an alternative to the user interface device represented by the hardware interface 1180) of a semiconductor system 1100 that includes the electronic device 1110, and which may further include sensors 1104 and/or semiconductor equipments 1106. The user terminal 1108 may output any of the above described identified factors or information on (or dependent on) such one or more factors (e.g., corresponding to operations S365 or S965 of FIGS. 3 and 9) to a user. The sensors 1104 may capture or measure the aforementioned respective measurement data on a plurality of measurement items with respect to any of the plurality of measurement items, and the semiconductor equipments 1106 may correspond to the aforementioned plurality of equipment pieces.

FIG. 12 illustrates a block diagram of the electronic device 100 according to an example embodiment.

According to an example embodiment, the electronic device 100 may include a memory 1200 and a processor 1250. The electronic device 100 illustrated in FIG. 12 illustrates only components related to the example embodiment. Therefore, it would be understood by those skilled in the art related to the present embodiment that other general components may be included in addition to the components illustrated in FIG. 12. In an example embodiment, the processor 1250 may be included in a controller.

The processor 1250 may control the overall operation of the electronic device 100 and process data and signals. The processor 1250 may consist of at least one hardware unit.

Further, the processor 1250 may be operated by one or more software modules generated by executing program code stored in the memory 1200. Since the processor 1250 may include memory, the processor 1250 may control the overall operation of the electronic device 100 and process data and signals by executing program code stored in memory 1200.

Using a first model, the processor 1250 may estimate, using the first model, respective first yields of a plurality of first wafers based on first data on a plurality of factors about the semiconductor manufacturing process regarding the plurality of first wafers, the first data obtained before the semiconductor manufacturing process of the plurality of first wafers has been completed, generate, using a second model generated based on the first model, respective yield contribution values of the plurality of factors based on the first data, data on the estimated respective first yields of the plurality of first wafers, second data on the plurality of factors regarding a plurality of second wafers of which the semiconductor manufacturing process has completed, and data on respective second yields of the plurality of second wafers and determine one or more factors, among the plurality of factors, that contribute to a yield reduction based on the generated respective yield contribution values of the plurality of factors.

None of the description in this application should be read as implying that any particular element, step, or function is an essential element that must be included in the claim scope. Moreover, none of the claims is intended to invoke 35 U.S.C. § 112(f) unless the exact words “means for” are followed by a participle. Use of any other term, including without limitation “mechanism,” “module,” “device,” “unit,” “component,” “element,” “member,” “apparatus,” “machine,” “system,” “processor,” or “controller,” within a claim is understood by the Applicant to refer to hardware structures known to those skilled in the relevant art and is not intended to invoke 35 U.S.C. § 112(f).

The electronic devices, transceivers, memories, processors, hardware interfaces, semiconductor equipment (i.e., the aforementioned plurality of equipment pieces), sensors, and user interfaces described herein, including descriptions with respect to respect to FIGS. 1-12, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (i.e., code) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-12 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method with respect to a semiconductor manufacturing process, the method comprising:
estimating, using a first model, respective first yields of a plurality of first wafers based on first data on a plurality of factors about the semiconductor manufacturing process regarding the plurality of first wafers, the first data obtained before the semiconductor manufacturing process of the plurality of first wafers has been completed;
generating, using a second model generated based on the first model, respective yield contribution values of the plurality of factors based on the first data, data on the estimated respective first yields of the plurality of first wafers, second data on the plurality of factors regarding a plurality of second wafers of which the semiconductor manufacturing process has completed, and data on respective second yields of the plurality of second wafers; and
determining one or more factors, among the plurality of factors, that contribute to a yield reduction based on the generated respective yield contribution values of the plurality of factors.

2. The method of claim 1,
wherein the plurality of factors include factors regarding a plurality of equipment pieces used in the semiconductor manufacturing process and factors regarding a plurality of measurement items that are measured in the semiconductor manufacturing process,
wherein data, among the first data, regarding one wafer of the plurality of first wafers includes category data on one or more pieces of first equipment used among the plurality of equipment pieces in a first process of the semiconductor manufacturing process performed with respect to the one wafer, category data on one or more pieces of second equipment predetermined among the plurality of equipment pieces to be used in a second process of the semiconductor manufacturing process with respect to the one wafer, measurement data on one or more first measurement items, among the plurality of measurement items, that have been measured with respect to the one wafer in the semiconductor manufacturing process, and measurement data on one or more second measurement items, among the plurality of measurement items, predetermined to be measured with respect to the first wafer in the semiconductor manufacturing process, and
wherein another data, among the second data, regarding another one wafer of the plurality of second wafers includes category data on the plurality of equipment pieces with respect to the other one wafer and measurement data on the plurality of measurement items with respect to the other one wafer.

3. The method of claim 2,
wherein the category data on the one or more pieces of second equipment includes corresponding data obtained based on process history of the one or more pieces of second equipment, and
wherein the measurement data on the one or more second measurement items includes other corresponding data obtained based on process history of the one or more second measurement items.

4. The method of claim 1, further comprising training the first model based on the second data and the data on the respective second yields of the plurality of second wafers.

5. The method of claim 1,
wherein the first model comprises a neural network including at least a plurality of layers, and
wherein the method further comprises generating the second model based on weights of the plurality of layers, where the second model comprises an explainable artificial intelligence (XAI) model.

6. The method of claim 1, wherein the determining of the one or more factors that contribute to the yield reduction comprises:
identifying date-dependent changes in respective yield reduction contribution rankings of the plurality of factors, based on the generated respective yield contribution values of the plurality of factors; and
identifying, as the determined one or more factors that contribute to the yield reduction, corresponding one or more factors, among the plurality of factors, of which the respective yield reduction contribution rankings rise based on the date-dependent changes in the respective yield reduction contribution rankings of the plurality of factors.

7. The method of claim 6, wherein the identifying of the date-dependent changes in the respective yield reduction contribution rankings of the plurality of factors comprises:
generating a plurality of wafer sets by grouping wafers for which an identical process in the semiconductor manufacturing process was performed on an identical date among the plurality of first wafers and the plurality of second wafers;
identifying the generated respective yield contribution values of the plurality of factors for each of the plurality of wafer sets; and
determining the respective yield reduction contribution rankings of the plurality of factors for each of the plurality of wafer sets based on the identified generated respective yield contribution values.

8. The method of claim 7, wherein a yield reduction contribution ranking of a first factor for a first wafer set among the respective yield reduction contribution rankings of the plurality of factors for each of the plurality of wafer sets includes one of:
a yield reduction contribution ranking corresponding to a date on which a first process of the semiconductor manufacturing process corresponding to the first factor is executed for the first wafer set;
a yield reduction contribution ranking corresponding to a date on which a second process of the semiconductor manufacturing process corresponding to the first factor is predetermined to be executed for the first wafer set;
a yield reduction contribution ranking corresponding to a completion date of the first wafer set with respect to the semiconductor manufacturing process; and
a yield reduction contribution ranking corresponding to an expected completion date of the first wafer set with respect to the semiconductor manufacturing process.

9. The method of claim 7, wherein the determined respective yield reduction contribution rankings of the plurality of factors for a first wafer set, among the determined respective yield reduction contribution rankings of the plurality of factors for each of the plurality of wafer sets, are determined to be higher as the identified respective yield contribution values of the plurality of factors for the first wafer set are lower.

10. The method of claim 7, wherein the identified generated respective yield contribution value of a first factor for a first wafer set, among the identified generated respective yield contribution values of the plurality of factors for each of the plurality of wafer sets, is determined as an average value of the generated respective yield contribution values of the first factor corresponding to wafers included in the first wafer set.

11. The method of claim 1,
wherein the plurality of first wafers include one wafer for which the semiconductor manufacturing process is set to be completed within a first period of time with reference to a set date, and
wherein the plurality of second wafers include another one wafer for which the semiconductor manufacturing process was completed within a second period of time with reference to the set date.

12. The method of claim 1, further comprising providing a user terminal with information on the determined one or more factors,
wherein the information on the determined one or more factors comprises at least one of information indicating date-dependent change in yield reduction contribution rankings of the determined one or more factors, information on equipment corresponding to the determined one or more factors, or information corresponding to a measurement item corresponding to the determined one or more factors.

13. A non-transitory computer-readable recording medium storing code, which when executed by one or more processors, configures the one or more processors to execute the method of claim 1.

14. An electronic device comprising:
a memory storing code; and
one or more processors configured to execute the code,
wherein, execution of the code by the one or more processors, configures the one or more processors to:
estimate, using a first model, respective first yields of a plurality of first wafers based on first data on a plurality of factors about the semiconductor manufacturing process regarding the plurality of first wafers, the first data obtained before the semiconductor manufacturing process of the plurality of first wafers has been completed;
generate, using a second model generated based on the first model, respective yield contribution values of the plurality of factors based on the first data, data on the estimated respective first yields of the plurality of first wafers, second data on the plurality of factors regarding a plurality of second wafers of which the semiconductor manufacturing process has completed, and data on respective second yields of the plurality of second wafers; and
determine one or more factors, among the plurality of factors, that contribute to a yield reduction based on the generated respective yield contribution values of the plurality of factors.

15. The electronic device of claim 14,
wherein the plurality of factors include factors regarding a plurality of equipment pieces used in the semiconductor manufacturing process and factors regarding a plurality of measurement items that are measured in the semiconductor manufacturing process,
wherein data, among the first data, regarding one wafer of the plurality of first wafers includes category data on one or more pieces of first equipment used among the plurality of equipment pieces in a first process of the semiconductor manufacturing process performed with respect to the one wafer, category data on one or more pieces of second equipment predetermined among the plurality of equipment pieces to be used in a second process of the semiconductor manufacturing process with respect to the one wafer, measurement data on one or more first measurement items, among the plurality of measurement items, that have been measured with respect to the one wafer in the semiconductor manufacturing process, and measurement data on one or more second measurement items, among the plurality of measurement items, predetermined to be measured with respect to the first wafer in the semiconductor manufacturing process, and
wherein another data, among the second data, regarding another one wafer of the plurality of second wafers includes category data on the plurality of equipment pieces with respect to the other one wafer and measurement data on the plurality of measurement items with respect to the other one wafer.

16. The electronic device of claim 15,
wherein the category data on the one or more pieces of second equipment includes corresponding data obtained based on process history of the one or more pieces of second equipment, and
wherein the measurement data on the one or more second measurement items includes other corresponding data obtained based on process history of the one or more second measurement items.

17. The electronic device of claim 14, wherein the execution of the code further configures the one or more processors to train the first model based on the second data and the data on the respective second yields of the plurality of second wafers.

18. The electronic device of claim 14,
wherein the first model comprises a neural network including at least a plurality of layers, and
wherein the execution of the code further configures the one or more processors to generate the second model based on weights of the plurality of layers, where the second model comprises an explainable artificial intelligence (XAI) model.

19. The electronic device of claim 14, wherein, for the determining of the one or more factors that contribute to the yield reduction, the execution of the code configures the one or more processors to:
identify date-dependent changes in respective yield reduction contribution rankings of the plurality of factors, based on the generated respective yield contribution values of the plurality of factors; and
identify, as the determined one or more factors that contribute to the yield reduction, corresponding one or more factors, among the plurality of factors, of which the respective yield reduction contribution rankings rise based on the date-dependent changes in the respective yield reduction contribution rankings of the plurality of factors.

20. The electronic device of claim 19, wherein, for the identifying of the date-dependent changes in the respective yield reduction contribution rankings of the plurality of factors, the execution of the code configures the one or more processors to:
generate a plurality of wafer sets by grouping wafers for which an identical process in the semiconductor manufacturing process was performed on an identical date among the plurality of first wafers and the plurality of second wafers;
identify the generated respective yield contribution values of the plurality of factors for each of the plurality of wafer sets; and
determine the respective yield reduction contribution rankings of the plurality of factors for each of the plurality of wafer sets based on the identified generated respective yield contribution values.
